(19) United States
(12) Patent Application Publication
(10) Pub. No.: US 2010/0230767 A1
(43) Pub. Date: Sep. 16, 2010

(54) MEMS SENSOR, MEMS SENSOR MANUFACTURING METHOD, AND ELECTRONIC DEVICE

(75) Inventors: Shigekazu TAKAGI, Shimosuwa (JP); Akira SATO, Fujimi (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/721,026

(22) Filed: Mar. 10, 2010

(30) Foreign Application Priority Data
Mar. 12, 2009 (JP) 2009-059048
Mar. 1, 2010 (JP) 2010-043844

(51) Int. Cl. H01L 29/84; H01L 21/02

(52) U.S. Cl. 257/417; 438/53; 257/E29.324; 257/E21.002

(57) ABSTRACT

An MEMS sensor includes: a movable weight which is connected with a fixed frame via an elastic deformation portion and has a cavity portion around the movable weight, wherein the movable weight has a laminated layer structure including a plurality of conductive layers, a plurality of between-layers insulation layers each of which is disposed between the adjoining conductive layers of the plural conductive layers, and plugs which are inserted into predetermined embedding groove patterns penetrating through the respective layers of the plural between-layers insulation layers and have specific gravity larger than that of the between-layers insulation layers, and the plugs formed on the respective layers have wall portions in wall shapes extending in one or plural longitudinal directions.

BACKGROUND

1. Technical Field

The present invention relates to an MEMS sensor (micro electro mechanical sensor), an MEMS sensor manufacturing method for manufacturing the MEMS sensor, electronic device, and others.

2. Related Art

An MEMS sensor such as a CMOS integrated circuit integral type silicon MEMS acceleration sensor has been rapidly decreasing its size and cost. On the other hand, the applications and the market of the MEMS sensor have been expanding. According to the typical device examples of the MEMS sensor, IC chips for converting physical quantities into electric signals and outputting the generated signals are produced as one package in a mounting process after a wafer process in most cases. For reducing the size and cost as much as possible, it is considered that such a technology for forming sensor chips and IC chips integrally with each other is necessary for the wafer process (see JP-A-2006-263902).

This type of MEMS sensor has such characteristics that the sensitivity rises as the mass of a movable weight increases. For increasing the mass of the movable weight, the movable weight has integral structure including multilayer wires produced simultaneously with the manufacture of an LSI multilayer wiring layer according to the technology disclosed in JP-A-2006-263902 (paragraph 0089, FIG. 25).

The movable weight oscillates in the vertical direction. The movable weight is constituted by only wiring layers. Between-layers insulation layers which have been once formed between the wiring layers but will be all removed cannot be used as weight. Moreover, since multilayer conductive layers provided on the movable weight are short-circuited between one another, all the potentials of the movable weight are equalized. In this case, stray capacitance produced by the use of the movable weight with a silicon substrate becomes a problem.

According to JP-A-2006-263902, FIG. 39 shows a structure which covers the periphery of the multilayer wiring structure with an insulation film (see paragraph 0114). As illustrated in FIG. 39 of this reference, the conductive layer below the movable weight is removed by etching. Thus, only two layers can be used as the multilayer wiring in the movable weight.

### SUMMARY

It is an advantage of some aspects of the invention to provide an MEMS sensor (such as an electrostatic capacity type acceleration sensor) and an MEMS sensor manufacturing method capable of efficiently increasing the mass of a movable weight. It is another advantage of some aspects of the invention to provide an MEMS sensor capable of detecting physical quantities such as acceleration with high accuracy, for example. It is a further advantage of some aspects of the invention to provide an MEMS sensor freely and easily produced by a CMOS process using multilayer wiring, for example.

An MEMS sensor according to a first aspect of the invention includes: a movable weight which is connected with a fixed frame via an elastic deformation portion and has a cavity portion around the movable weight. The movable weight has a laminated layer structure including: a plurality of conductive layers; a plurality of between-layers insulation layers each of which is disposed between the adjoining conductive layers of the plural conductive layers; and plugs which are inserted into predetermined embedding groove patterns penetrating through the respective layers of the plural between-layers insulation layers and have specific gravity larger than that of the between-layers insulation layers; and the plugs formed on the respective layers have wall portions in wall shapes extending in one or plural longitudinal directions. In another embodiment, An MEMS sensor comprising: a movable weight which is connected with a fixed frame via an elastic deformation portion, wherein the movable weight has a laminated layer structure including a conductive layer and an insulation layer, the insulation layer is embedded a plug, and the plug has specific gravity larger than that of the insulation layer.

According to this structure, the movable weight which can decrease sensitivity noise as the mass of the weight increases can be formed as a laminated layer structure including the plural conductive layers, the plural between-layers insulation layers, and the plugs on the respective layers disposed with high density. Thus, the plugs contribute to increase in the mass of the movable weight per unit volume. Moreover, the laminated layer structure constituting the movable weight is produced by ordinary CMOS process. In this case, the MEMS sensor can be easily disposed together with the integrated circuit unit on the same substrate. In addition, the number of the conductive layers can be increased relatively easily, which improves the degree of designing freedom. For example, the mass of the movable weight can be raised by increasing the number of the layers to meet the demand for noise reduction for acceleration sensors.

It is possible that the MEMS sensor further includes: at least one fixed electrode unit fixed to the fixed frame; and a plurality of movable electrode units which are formed integrally with the movable weight and move at least in one axial direction to increase and decrease the distance between the plural movable electrode units and the at least one fixed electrode unit. In another embodiment, a fixed electrode unit extending from the fixed frame in the form of a arm; and a movable electrode unit extending from the movable weight and disposed opposed to the fixed electrode unit through a gap in the form of a arm, wherein the fixed electrode unit and the movable electrode unit are arranged a first direction.

In this case, the plural movable electrode units are provided on the laminated layer structure. Since the electrodes are formed in wall shape by using the plugs and the wiring layers on the respective layers, the absolute value of the opposed electrode capacitance can be made larger than that of a structure including electrodes formed by only wiring layers.

The physical quantity detection principle is based on the fact that the level and direction of the physical quantity can be detected from increase in one of the two between-electrodes distances and decrease in the other between-electrodes distance produced when the plural movable electrode units move along with the movable weight with respect to the at least one fixed electrode unit, for example, according to the relationship between the level of the electrostatic capacity and the increase and decrease dependent on the between-electrodes distances. The movable electrode units formed by the laminated layer structure of the movable weight can contribute to increase in the mass of the movable weight as well as the function of electrodes. It is possible to use only opposed electrodes having a variable distance when only detection of the level of the physical quantity is desired.

It is possible that the movable weight has a plane including the first direction and a second direction perpendicular to the first direction in planar view, and the movable weight has a center line bisected with a width of the second direction, and the plug is formed line symmetry for the center line in the movable weight.

According to this structure, when the movable weight is displaced by force from external, it is improved the balance of the movable weight.

It is possible that the movable weight has a through hole penetrated from a top layer to a bottom layer; the plug is formed in proximity to the through hole.

According to this structure, when the movable weight lightens by the through hole, the mass of the movable weight can be raised by the plug.

It is possible that the potentials of the plural movable electrode units are set at equal potentials by a wire using all or a part of the plural conductive layers and the plugs on the respective layers of the movable weight. Alternatively, it is possible that the potentials of the plural movable electrode units are set at different potentials by electrically insulated plural wires using all or a part of the plural conductive layers and the plugs on the respective layers of the movable weight. According to the physical quantity detection principle described above, a combination of at least two types of fixed electrode potential and one type of movable electrode potential or a combination of at least two types of movable electrode potential and one type of fixed electrode potential is required. Thus, the movable electrode potentials need to be set at equal potentials or different potentials.

It is possible that each of the plural conductive layers includes a plurality of first conductive layers and a plurality of second conductive layers electrically insulated from one another, and that each of the plugs provided on the respective layers includes a first plug connecting the plural first conductive layers to one another and a second plug connecting the plural second conductive layers to one another. The plural first conductive layers and the first plugs are electrically connected with the movable electrode units. The plural second conductive layers and the second plugs are set in electrically floating condition.

According to this structure, the problem of stray capacitance produced by the use of the movable weight with a silicon substrate or the like under the condition that all the potentials of the movable weight are equalized can be eliminated. More specifically, the plural second conductive layers and the second plugs set in electrically floating condition can independently contribute to increase in the mass of the movable weight without electrically affecting the outside.

It is preferable that the number of the conductive layers provided on the elastic deformation portion is smaller than the number of the plural conductive layers provided on the movable weight. Particularly, only one conductive layer is provided on the elastic deformation portion with no plug formed on the elastic deformation portion.

According to this structure, the number of the conductive layers and the plugs having high rigidity is reduced. Thus, the elastic force can be easily designed. When plural types of conductive layers having different thermal expansion coefficients are used, the conductive layers are deformed with temperature change. However, when only one conductive layer is used, the effect of deformation caused by temperature can be ignored. Thus, the elastic deformation portion can be easily deformed with elasticity, and the use of the conductive layer on the elastic deformation portion as wire can be secured. When the movable weight is supported by plural elastic deformation portions, the spring constants of the plural elastic deformation portions need to be equalized.

It is possible that the MEMS sensor further includes: a substrate on which the laminated layer structure is formed; and an integrated circuit unit provided on the substrate adjacent to the laminated layer structure. The plural conductive layers, the plural between-layers insulation layers, and the plugs on the respective layers are produced by a process for manufacturing the integrated circuit unit.

As described above, the laminated layer structure of the movable weight can be manufactured by the CMOS process. Thus, the MEMS sensor can be mounted together with the integrated circuit unit on the same substrate. In this case, the manufacturing cost can be made lower than that when the MEMS sensor and the integrated circuit unit are manufactured and assembled in separate processes. Moreover, the wiring distance can be reduced by providing the CMOS integrated circuit unit and the MEMS structure as monolithic units. In this case, reduction in losses produced by drawing wires, and increase in resistance to noise coming from the outside can be achieved.

It is possible that the movable weight further has an insulation layer covering the lowest conductive layer. In this case, a part of the cavity portion communicates with an area below the insulation layer.

According to this structure, the mass of the movable weight can be increased by the amount of the insulation layer, and the lowest conductive layer can be protected without exposure.

It is possible that the lowest conductive layer is made of material of a gate electrode of a transistor provided on the integrated circuit unit. In this case, the insulation layer includes a field oxide film of the integrated circuit unit.

According to this structure, the mass of the movable weight can be further increased by providing the conductive layer as the lowest layer in the CMOS process and the insulation layer on the movable weight.

It is possible to further provide a protection layer for covering the highest conductive layer on the movable weight. In this case, the mass of the movable weight can be increased by the amount of the protection layer, and the highest conductive layer can be protected without exposure. An MEMS sensor manufacturing method according to a second aspect of the invention for manufacturing the MEMS sensor according to the first aspect of the invention includes: forming a laminated layer structure which includes a plurality of conductive layers, a plurality of between-layers insulation layers each of which is disposed between the adjoining conductive layers of the plural conductive layers, and plugs which are inserted into predetermined embedding groove patterns penetrating through the respective layers of the plural between-layers insulation layers and have specific gravity larger than that of the between-layers insulation layers on a substrate; patterning the laminated layer structure by anisotropic etching to form a first cavity portion as an opening through which the surface of the substrate is exposed, and forming an elastic deformation portion and a movable weight connected with a fixed frame via the elastic deformation portion by using the first cavity portion; and isotropically etching the substrate by applying etchant for isotropic etching to the substrate through the opening to form a second cavity portion below the laminated layer structure. In another embodiment, An MEMS sensor manufacturing method for an MEMS sensor having a movable weight which is connected with a fixed frame via an elastic deformation portion, comprising: forming a laminated layer structure which laminates a conductive layer and a insulation layer on a substrate; forming a groove on the insulation layer, and inserting a plug in the groove, the plug has specific gravity larger than that of the insulation layer; patterning the laminated layer structure by anisotropic etching to form a first cavity portion as an opening through which the surface of the substrate is exposed; and isotropically etching the substrate via the first cavity portion to form a second cavity portion between the substrate and the laminated layer structure.

According to the second aspect of the invention, the MEMS sensor including the movable weight connected with the fixed frame via the elastic deformation portion and having the cavity portion around the movable weight can be manufactured in a preferable manner by combining anisotropic etching and isotropic etching.

It is possible that the electronic device comprises the MEMS sensor.

According to this structure, it is able to improve detection sensitivity by the MEMS sensor.

### BRIEF DESCRIPTION OF THE DRAWINGS

The invention will be described with reference to the accompanying drawings, wherein like numbers reference like elements.

FIG. 1 is a plan view of an acceleration sensor module according to a first embodiment of the invention, showing the internal structure of the acceleration sensor module.

FIG. 2 is a cross-sectional view taken along a line A-A in FIG. 1.

FIG. 3 is a cross-sectional view taken along a line B-B in FIG. 1.

FIG. 4 is a block diagram of the acceleration sensor module.

FIGS. 5A through 5D schematically illustrate a process for manufacturing the acceleration sensor module according to the first embodiment of the invention.

FIG. 6 is a plan view showing a first conductive layer.

FIG. 7 is a plan view showing a first plug layer.

FIG. 8 is a cross-sectional view showing the first and second conductive layers and the first plug layer connecting the first and second conductive layers.

FIGS. 9A through 9E illustrate end shapes of embedding groove patterns for inserting the plug.

FIG. 10 is a plan view showing a second conductive layer.

FIG. 11 is a plan view showing a second plug layer.

FIG. 12 is a plan view showing a third conductive layer.

FIG. 13 is a plan view showing a third plug layer.

FIG. 14 is a plan view showing a fourth conductive layer.

FIG. 15 is a plan view showing a protection layer.

FIG. 16 is a plan view of an acceleration sensor module according to a second embodiment of the invention, showing the internal structure of the acceleration sensor module.

FIG. 17 is a cross-sectional view taken along a line A-A in FIG. 16.

FIG. 18 is a cross-sectional view taken along a line B-B in FIG. 16.

FIG. 19 is a plan view showing a first conductive layer.

FIG. 20 is a plan view showing a first plug layer.

FIG. 21 is a plan view showing a second conductive layer.

FIG. 22 is a plan view showing a second plug layer.

FIG. 23 is a plan view showing a third conductive layer.

FIG. 24 is a plan view showing a third plug layer.

FIG. 25 is a plan view showing a fourth conductive layer.

FIG. 26 is a plan view of an acceleration sensor module according to a third embodiment of the invention, showing the internal structure of the acceleration sensor module.

FIG. 27 is a plan view showing a first conductive layer.

FIG. 28 is a plan view showing a first plug layer.

FIG. 29 is a plan view showing a second conductive layer.

FIG. 30 is a plan view showing a second plug layer.

FIG. 31 is a plan view showing a third conductive layer.

FIG. 32 is a plan view showing a third plug layer.

FIG. 33 is a plan view showing a fourth conductive layer.

FIG. 34 is a plan view of an acceleration sensor module according to a fourth embodiment of the invention, showing the internal structure of the acceleration sensor module.

FIG. 35 is a plan view of an acceleration sensor module according to a fifth embodiment of the invention, showing the internal structure of the acceleration sensor module.

FIG. 36 is a cross-sectional view taken along a line A-A in FIG. 35.

FIG. 37 is a plan view showing a first conductive layer.

FIG. 38 is a plan view showing a first plug layer.

FIG. 39 is a plan view showing a second conductive layer.

FIG. 40 is a plan view showing a second plug layer.

FIG. 41 is a plan view showing a third conductive layer.

FIG. 42 is a plan view showing a third plug layer.

FIG. 43 is a plan view showing a fourth conductive layer.

FIG. 44 is a plan view of an acceleration sensor module according to a sixth embodiment of the invention, showing the internal structure of the acceleration sensor module.

FIG. 45 is a cross-sectional view taken along a line A-A in FIG. 44.

FIG. 46 is a plan view of an acceleration sensor module according to a seventh embodiment of the invention, showing the internal structure of the acceleration sensor module.

FIG. 47 is a plan view showing a first conductive layer.

FIG. 48 is a plan view showing a first plug layer.

FIG. 49 is a plan view showing a second conductive layer.

FIG. 50 is a plan view showing a second plug layer.

FIG. 51 is a plan view showing a third conductive layer.

FIG. 52 is a plan view showing a third plug layer.

FIG. 53 is a plan view showing a fourth conductive layer.

FIGS. 54A through 54C illustrate the structure and operation of a C/V conversion circuit (charge amplifier).

### DESCRIPTION OF EXEMPLARY EMBODIMENTS

Preferred embodiments according to the invention are hereinafter described in detail. It is intended that the scope of the invention defined by the appended claims should not be construed to be limited by the embodiments described and depicted herein. As such, all of the structures explained herein are not necessarily essential to the solutions provided by the invention.

### 1. First Embodiment

According to a first embodiment, sensor chips and IC chips are integrally formed by a wafer process.

### 1.1 Movable Weight

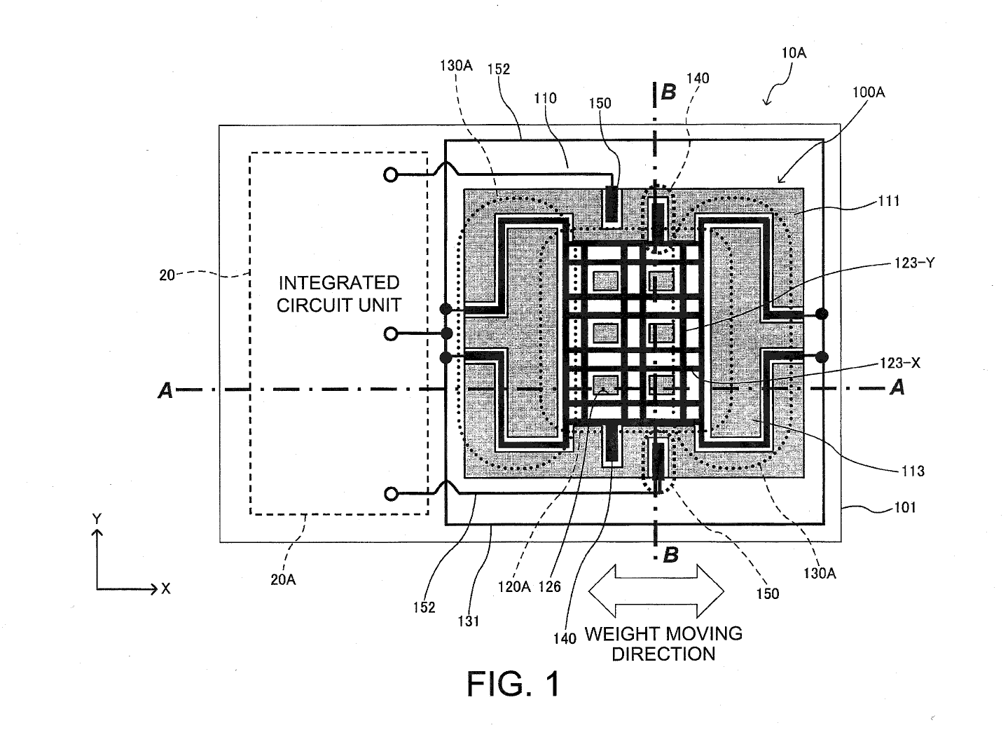

FIG. 1 schematically illustrates an acceleration sensor module 10A including an acceleration sensor 100A according to the first embodiment as an example of an MEMS sensor of the invention. The acceleration sensor module 10A includes an integrated circuit unit 20A as well as the acceleration sensor 100A. The acceleration sensor 100A is produced by a process for manufacturing the integrated circuit unit 20A.

The acceleration sensor 100A includes a movable weight 120A movable within a cavity portion 111 inside a fixed frame 110. The movable weight 120A has predetermined mass. When acceleration is exerted on the stationary movable weight 120A, for example, a force in the direction opposite to the acceleration direction acts on the movable weight 120A to move the movable weight 120A.

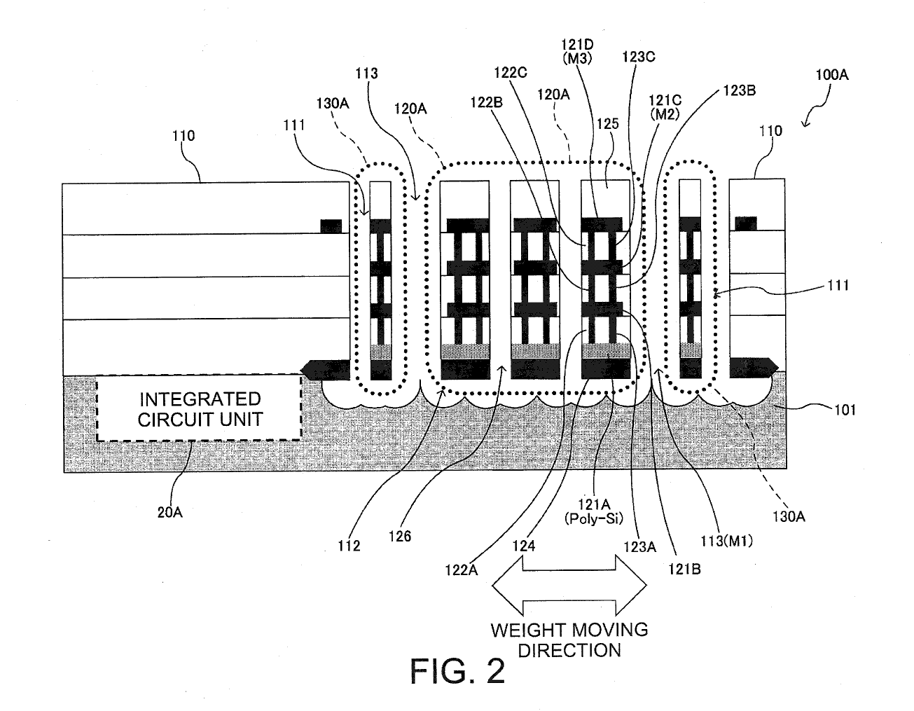

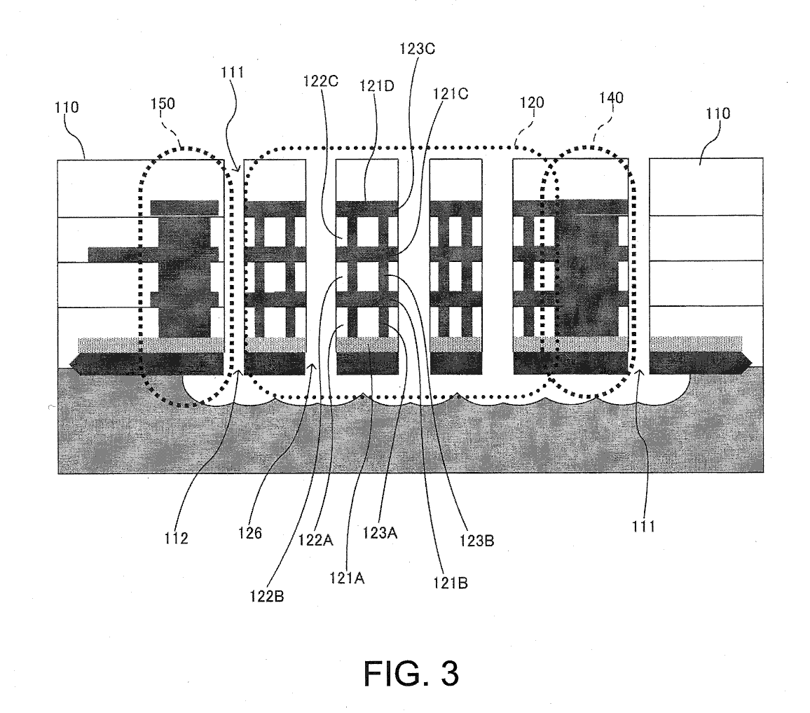

As illustrated in FIG. 2 as a cross-sectional view taken along a line A-A in FIG. 1 and FIG. 3 as a cross-sectional view taken along a line B-B in FIG. 1, the movable weight 120A includes a plurality of conductive layers 121A through 121D, a plurality of between-layers insulation layers 122A through 122C each of which is disposed between the corresponding adjoining layers of the plural conductive layers 121A through 121D, and plugs 123A through 123C inserted into predetermined embedding groove patterns penetrating the plural between-layers insulation layers 122A through 122C. The predetermined embedding groove patterns penetrating the plural between-layers insulation layers 122A through 122C are grid patterns, for example, and the plugs 123A through 123C are formed in the shape of grids. It is required that the plugs 123A through 123C are made of material having specific gravity larger than that of the between-layers insulation films 122A through 122C. When the plugs 123A through 123C are used to provide conduction as well, the plugs 123A through 123C are made of conductive material.

According to this embodiment, the lowest conductive layer 121A is a polysilicon layer formed on an insulation layer 124 on a silicon substrate 101 of the integrated circuit unit 20A. The other three conductive layers 121B through 121D are metal layers.

The plugs 123A through 123C formed on the respective layers include wall portions in the wall shape extending one or plural longitudinal directions orthogonal to the lamination direction of the respective layers. As illustrated in FIG. 1, two orthogonal axes in the two-dimensional plane are defined as X and Y directions. In this embodiment, each of the plugs 123A through 123C formed on the respective layers has a plug 123-X extending in the wall shape in the X direction as the longitudinal direction, and a plug 123-Y extending in the wall shape in the Y direction as the longitudinal direction.

Accordingly, the structure of the movable weight 120A in this embodiment includes the plural conductive layers 121A through 121D, the between-layers insulation layers 122A through 122C, and the plugs 123A through 123C similarly to the structure of an ordinary IC cross section. Thus, the movable weight 120A can be produced by the process for manufacturing the integrated circuit unit 20A. Moreover, all the parts formed by the process for manufacturing the integrated circuit unit 20A can be used for increasing the weight of the movable weight 120A.

Particularly, the movable weight 120A produced by the IC manufacturing process is designed such that the plugs 123A through 123C provided on the respective layers can increase the mass of the movable weight 120A. As explained above, the plugs 123A through 123C formed on the respective layers and including the two types of plugs 123-X and 123-Y increase the weight by the wall portions of the respective plugs 123-X and 123-Y.

In this embodiment, the insulation layer 124 is provided on the lower surface of the lowest conductive layer 121A to further increase the weight of the movable weight 120A. In addition, a protection layer 125 is provided to cover the highest conductive layer 121D.

For moving the movable weight 120A, a space is required not only in the cavity portion 111 disposed on the side of the movable weight 120A but also on the upper and lower sides. Thus, an area of the silicon substrate 101 below the insulation layer 124 as the lowest layer of the movable weight 120A is etched to form a cavity portion 112.

The movable weight 120A has one or plural through holes 126 vertically penetrating an area on which the plugs 123A through 123C are not formed. The through hole 126 is formed as gas passage used to form the cavity portion 112 by the etching process. Since the weight of the movable weight 120A decreases according to the volume of the through hole 126, the hole diameter and the number of the through hole 126 are determined within the allowable range for carrying out the etching process.

In addition, the fixed electrode unit and the movable electrode unit are arranged a first direction. The movable weight has a plane including the first direction and a second direction perpendicular to the first direction in planar view, and the movable weight has a center line bisected with a width of the second direction, and the plug is formed line symmetry for the center line in the movable weight.

According to this structure, when the movable weight is displaced by force from external, it is improved the balance of the movable weight.

In addition, it is possible that the movable weight has a through hole 126 penetrated from a top layer to a bottom layer; the plug is formed in proximity to the through hole 126.

According to this structure, when the movable weight lightens by the through hole, the mass of the movable weight can be raised by the plug.

### 1.2 Elastic Deformation Portion

Elastic deformation portions 130A are provided such that the movable weight 120A can be movably supported by the cavity portion 111 disposed on the side and the cavity portion 112 disposed below as described above. The elastic deformation portions 130A are interposed between the fixed frame 110 and the movable weight 120A.

The elastic deformation portions 130A can elastically deform to allow the movable weight 120A to move in the weight moving direction (X direction) in FIG. 1. As illustrated in FIG. 1, each of the elastic deformation portions 130A has a loop shape having a substantially constant line width in the plan view, and connects with the fixed frame 110. The elastic deformability of the elastic deformation portions 130A is secured by providing cavity portions (first cavity portions) 113 sectioned from the cavity portion 111.

Similarly to the movable weight 120A, the elastic deformation portions 130A are produced by the process for manufacturing the integrated circuit unit 20A. Thus, each of the elastic deformation portions 130A includes the plural conductive layers 121A through 121D, the plural between-layers insulation layers 122A through 122C, the plural plugs 123A through 123C, the insulation layer 124, and the protection layer 125.

### 1.3 Movable Electrode Unit And Fixed Electrode Unit

The device provided according to this embodiment is a capacitive acceleration sensor which includes a movable electrode unit 140 and a fixed electrode unit 150 whose gaps between opposed electrodes vary by the action of acceleration. The movable electrode unit 140 is formed integrally with the movable weight 120A, and the fixed electrode unit 150 is formed integrally with the fixed frame 110.

Similarly to the movable weight 120A, the movable electrode unit 140 and the fixed electrode unit 150 are produced by the process for manufacturing the integrated circuit unit 20A. That is, each of the movable electrode unit 140 and the fixed electrode unit 150 includes the plural conductive layers 121A through 121D, the plural between-layers insulation layers 122A through 122C, the plural plugs 123A through 123C, the insulation layer 124, and the protection layer 125 as illustrated in FIG. 3. However, only the plural conductive layers 121A through 121D of the electrode units 140 and 150 function as electrode units.

### 1.4 Detection Principle of Acceleration Sensor

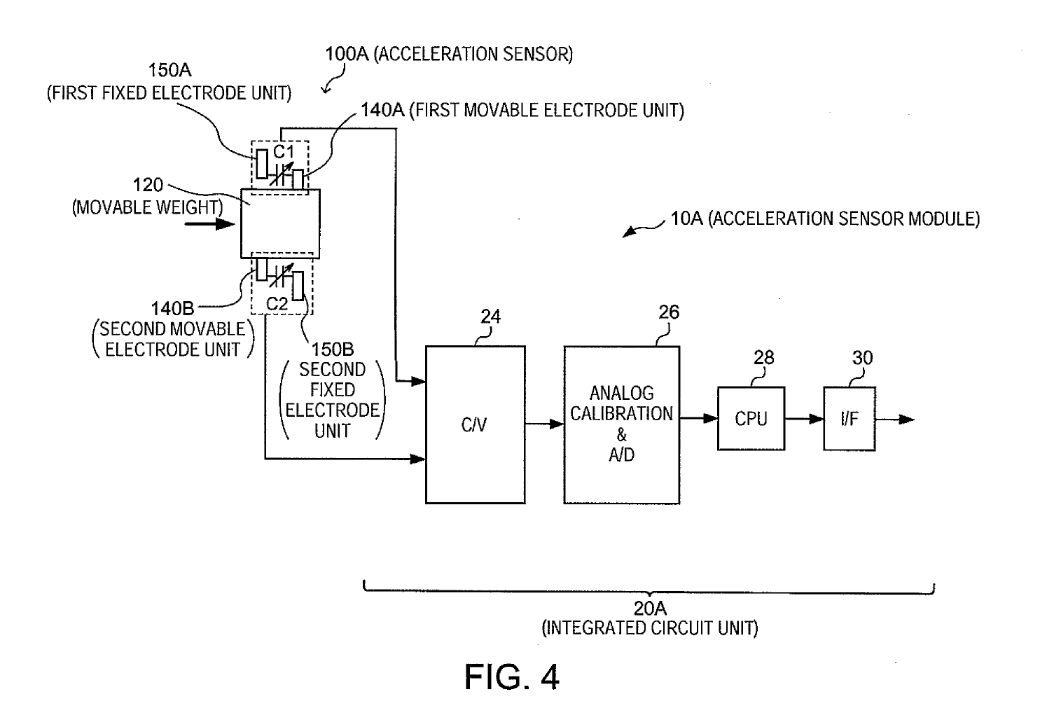

FIG. 4 is a block diagram showing the acceleration sensor module 10A according to this embodiment. The acceleration sensor 100A includes two pairs of the movable and fixed electrodes provided with a first movable electrode unit 140A, a second movable electrode unit 140B, a first fixed electrode unit 150A, and a second fixed electrode unit 150B. A capacitor C1 is constituted by the first movable electrode unit 140A and the first fixed electrode unit 150A. A capacitor C2 is constituted by the second movable electrode unit 140B and the second fixed electrode unit 150B. One of the potentials of the electrodes included in each of the capacitors C1 and C2 (such as the potential of the fixed electrode unit) is fixed at a reference potential (such as grounding potential). According to the structure shown in FIG. 1, the potential of the movable electrode unit is fixed at the reference potential (such as grounding potential).

The integrated circuit unit 20A includes a C/V conversion circuit 24, an analog calibration and A/D conversion circuit unit 26, a central processing unit (CPU) 28, and an interface (I/F) circuit 30, for example. This structure is shown only as an example, and other structures may be employed. For example, the CPU 28 may be replaced with a control logic. Also, the A/D conversion circuit may be disposed on the output section of the C/V conversion circuit 24.

When acceleration is exerted on the stationary movable weight 120A, a force in the direction opposite to the acceleration direction acts on the movable weight 120A. As a result, the gap between each pair of the movable and fixed electrodes varies. When the movable weight 120A shifts in a direction indicated by an arrow in FIG. 4, the gap between the first movable electrode unit 140A and the first fixed electrode unit 150A increases. In this case, the gap between the second movable electrode unit 140B and the fixed electrode unit 150B decreases. The length of the gap is inversely proportional to electrostatic capacity. Thus, the electrostatic capacity of the capacitor C1 constituted by the movable electrode unit 140A and the fixed electrode unit 150A decreases, and the electrostatic capacity of the capacitor C2 constituted by the movable electrode unit 140B and the fixed electrode unit 150B increases. As a result, the charge moves by the changes of the capacities of the capacitors C1 and C2. The C/V conversion circuit 24 has a charge amplifier including a switched capacitor. The charge amplifier converts small current signals produced by the movement of the charge into voltage signals by sampling operation and integration (amplification) operation. The voltage signals outputted from the C/V conversion circuit 24 (that is, physical quantity signals detected by a physical quantity sensor) are calibrated by the analog calibration and A/D conversion circuit unit 26 (such as phase and signal amplitude adjustments). During the calibration, low-pass filter process may be further carried out. Then, the processed voltage signals as analog signals are converted into digital signals.

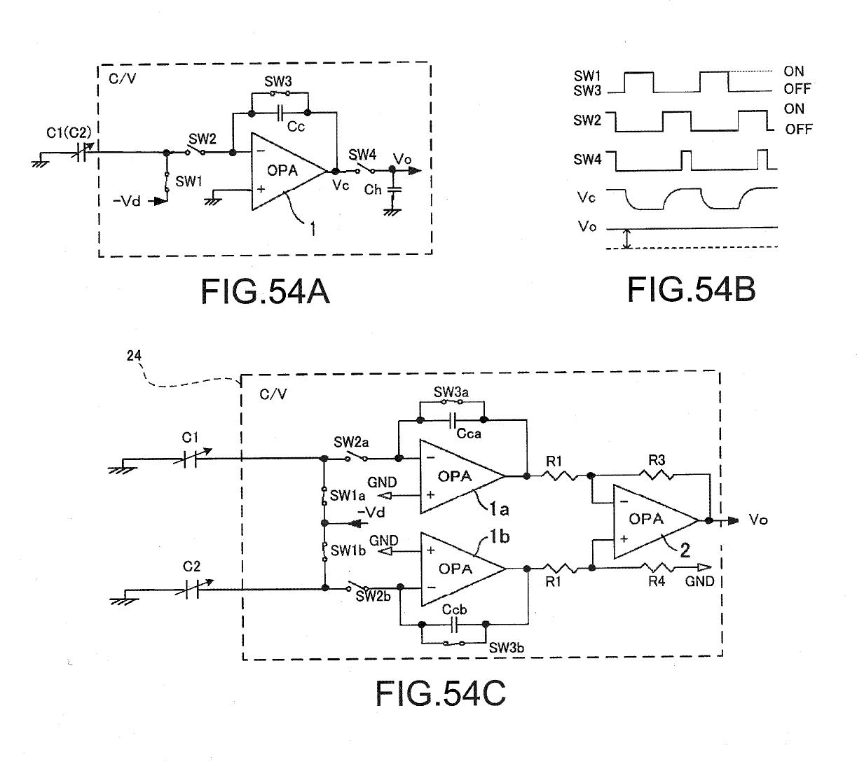

The structure and the operation of the C/V conversion circuit 24 are now explained with reference to FIGS. 54A through 54C. FIG. 54A shows the basic structure of the charge amplifier including the switched capacitor, and FIG. 54B shows voltage waveforms at the respective sections of the charge amplifier shown in FIG. 54A.

As illustrated in FIGS. 54A through 54C, the C/V conversion circuit 24 includes a first switch SW1 and a second switch SW2 (constituting a switched capacitor of an input section with the variable capacitor C1 (or C2)), an operation amplifier (OPA) 1, a feedback capacitor (integration capacity) Cc, a third switch SW3 for resetting the feedback capacitor Cc, a fourth switch SW4 for sampling an output voltage Vc from the operation amplifier (OPA) 1, and a holding capacitor Ch.

As shown in FIG. 54B, the first switch SW1 and the third switch SW3 are turned on and off by a first clock having the same phase. The second switch SW2 is turned on and off by a second clock having the phase opposite to that of the first clock. The fourth switch SW4 is turned on for a short period in the final stage while the second switch SW2 is turned on. When the first switch SW1 is turned on, a predetermined voltage Vd is applied to both the ends of the variable capacitor C1 (C2). As a result, charges are accumulated on the variable capacitor C1 (C2). At this time, the feedback capacitor Cc is in the reset condition (the condition in which both ends are short circuited) under the turned-on condition of the third switch SW3. Then, the first switch SW1 and the third switch SW3 are turned off, and the second switch SW2 is turned on. As a result, the potentials at both ends of the variable capacitor C1 (C2) become grounding potentials, and the charges accumulated on the variable capacitor C1 (C2) move toward the operation amplifier (OPA) 1. In this case, the equation Vd·C1 (C2)=Vc·Cc holds due to conservation of the charge quantity, and thus the output voltage Vc from the operation amplifier (OPA) 1 becomes (C1/Cc)·Vd. That is, the gain of the charge amplifier is determined by the ratio of the capacity of the variable capacitor C1 (or C2) to the capacity of the feedback capacitor Cc. When the fourth switch (sampling switch) SW4 is turned on in the subsequent step, the output voltage Vc from the operation amplifier (OPA) 1 is held by the holding capacitor Ch. The held voltage is a voltage Vo which becomes the output voltage from the charge amplifier.

As illustrated in FIG. 4, the C/V conversion circuit 24 in the practical structure receives differential signals from each of the two capacitors C1 and C2. In this case, the C/V conversion circuit 24 may be constituted by a charge amplifier having differential structure shown in FIG. 54C, for example. The charge amplifier shown in FIG. 54C includes a first switched capacitor amplifier (SW1a, SW2a, OPA1a, Cca, and SW3a) for amplifying the signals from the variable capacitor C1, and a second switched capacitor amplifier (SW1b, SW2b, OPA1b, Ccb, and SW3b) for amplifying the signals from the variable capacitor C2 at the input section. The output signals from the operation amplifiers (OPA) 1a and 1b (differential signals) are inputted to a differential amplifier (OPA2 and resistors R1 through R4) provided at the output section. As a result, an amplified output signal Vo is outputted from the operation amplifier (OPA) 2. By using the differential amplifier, base noise can be removed.

The structure of the C/V conversion circuit explained herein is only an example, and other structures may be employed. While FIG. 4 shows only two pairs of the movable and fixed electrodes for simplifying the explanation, the number of the pairs of the electrodes may be increased according to the necessary capacitance. In practical use, several tens to several hundreds of pairs of the electrodes are provided, for example.

### 1.5 Manufacturing Method

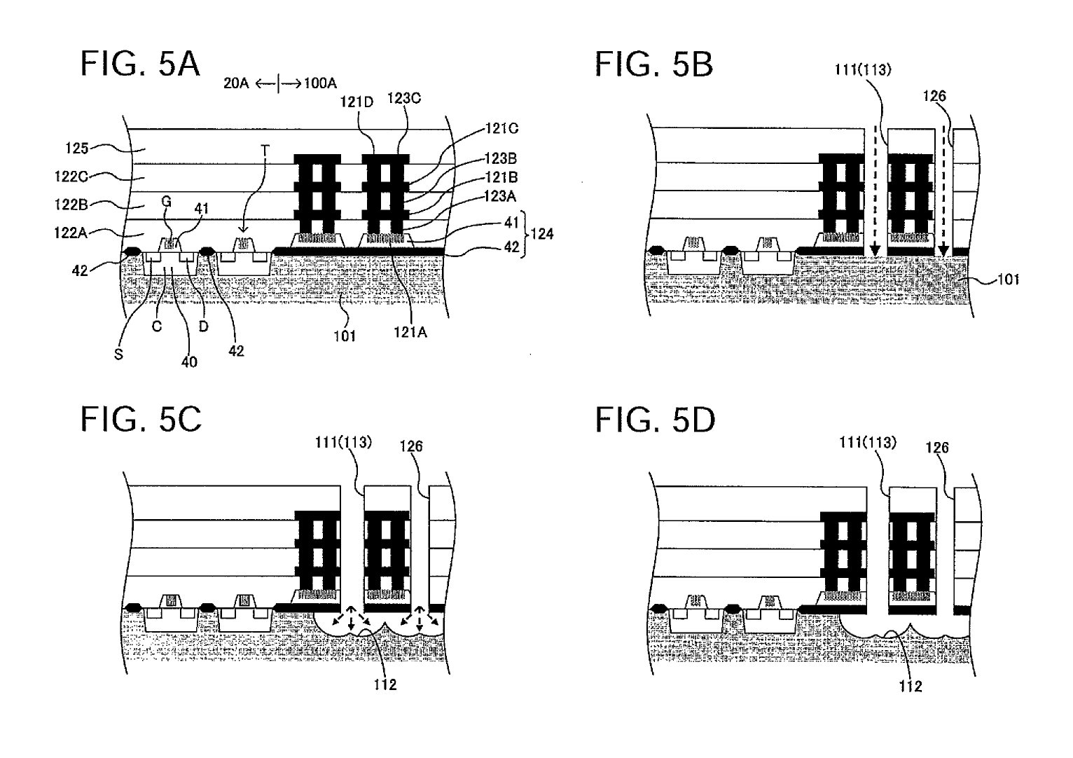

A manufacturing method of the acceleration sensor module 10A shown in FIG. 1 is roughly described with reference to FIGS. 5A through 5D. FIG. 5A shows the finished CMOS integrated circuit unit 20A and the unfinished acceleration sensor 100A. The CMOS integrated circuit unit 20A shown in FIG. 5A is produced by a known process. Wells 40 having polarity different from that of a substrate such as the silicon substrate 101 are formed on the silicon substrate 101. A source S, a drain D, and a channel C are formed within each of the wells 40. A gate electrode G is formed on the channel C via a gate oxide film 41. A thermal oxide film 42 as a field oxide film is formed on a field area for element division and the area of the acceleration sensor 100A. After transistors T having this structure are formed on the silicon substrate 101, wires are connected with the transistors T to complete the CMOS integrated circuit unit 20A. In this embodiment, the sources S, the drains D, and the gates G of the transistors T are connected with wires by the conductive layers 121A through 121C and the plugs 123A through 123C (not shown on the transistors T) formed between the between-layers insulation layers 122A through 122C shown in FIG. 5A.

By this method, the acceleration sensor 100A including the plural conductive layers 121A through 121D, the plural between-layers insulation layers 122A through 122C, the plural plugs 123A through 123C, the insulation layer 124, and the protection layer 125 necessary for the manufacture of the CMOS integrated circuit unit 20A can be produced. The insulation layer 124 below the lowest conductive layer (such as polysilicon layer) 121A corresponds to the gate oxide film 41 and the thermal oxide film 42.

FIG. 5B shows a step for manufacturing the cavity portion 111, the cavity portions 113, and the through hole 126 (all of these correspond to the first cavity portion). In the step shown in FIG. 5B, holes penetrating the area from the surface of the protection layer 125 to the surface of the silicon substrate 101 are formed by etching the between-layers insulation layers 122A through 122C, the insulation layer 124, and the protection layer 125. This etching process is insulation film anisotropic etching having a high aspect ratio (H/D) of etching depth (such as 4 to 6 μm) to opening diameter D (such as 1 μm). By the etching process, the fixed unit 110, the movable weight 120A, and the elastic deformation portions 130A are separated from one another.

It is possible that the anisotropic etching is performed under the condition for etching between-layers insulation films provided between wiring layers of an ordinary CMOS. For example, the process can be carried out by dry-etching using mixed gas of CF₄ and CHF₃.

FIG. 5C shows a silicon isotropic etching process for forming the cavity portion (second cavity portion) 112. FIG. 5D illustrates the acceleration sensor 100A completed after the etching step shown in FIG. 5C. In the etching step shown in FIG. 5C, the silicon substrate 101 below the movable weight 120A, the elastic deformation portions 130A, and the movable electrode unit 140 is etched by using the cavity portion 111, the cavity portions 113, and the through hole 126 as openings. For etching silicon, such a method is known which introduces etching gas XeF₂ to a wafer disposed within an etching chamber. This etching gas does not require plasma excitation but allows gas etching. For example, XeFe₂ can etch under pressure of 5 kPa as disclosed in JP-A-2002-113700. Also, XeF₂ can etch under vapor pressure of about 4 Torr or lower, expecting an etching rate of 3 to 4 μm/min. Alternatively, it is possible to employ ICP etching. In this case, when RF power of about 100 W is supplied using mixed gas of SF₆ and O₂ and setting the pressure inside the chamber at 1 to 100 Pa, for example, 2 to 3 μm can be etched in several minutes.

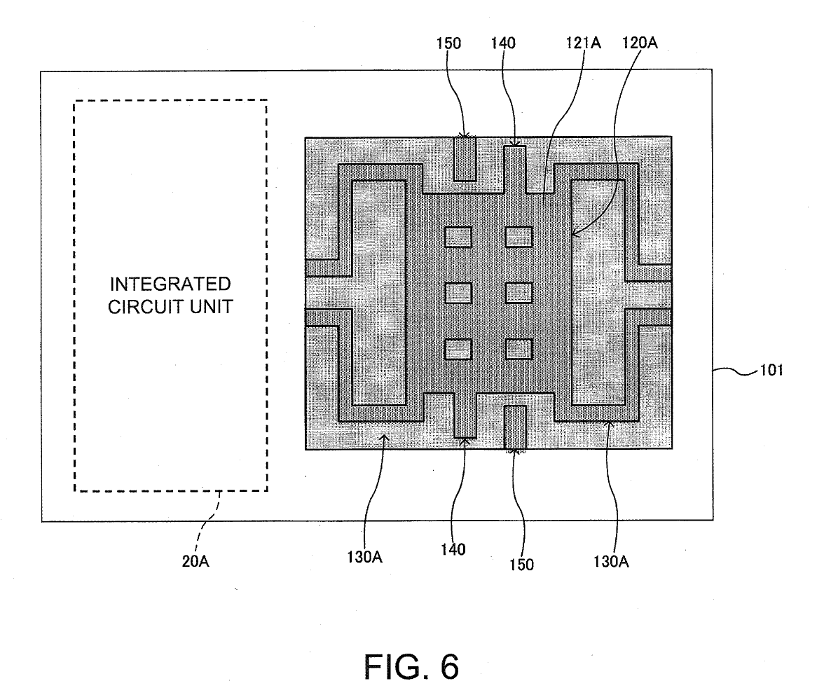

A process for producing the conductive layers 121A through 121C and the plugs 123A through 123C included in the process for producing the acceleration sensor 100A by the process for manufacturing the CMOS integrated circuit unit 20A is now explained with reference to FIGS. 6 through 15. FIG. 6 shows a step for producing the first conductive layer 121A. The first conductive layer 121A is produced simultaneously with the step for producing the gate electrodes G shown in FIG. 5A. According to this embodiment, a polysilicon layer (Poly-Si) having film thickness of 100 to 5000 A (angstrom, hereinafter abbreviated as “A”) is formed by CVD (chemical vapor deposition), and etched by a photolithography step to produce the pattern of the first conductive layer 121A. The first conductive layer 121A can be made from silicide, metal having high melting point, or others as well as polysilicon. The pattern of the first conductive layer 121A is formed on an area other than the area corresponding to the cavity portion 111, the cavity portions 113, and the through holes 126 shown in FIG. 1. The first conductive layer 121A has a pattern corresponding to the contour shape of the movable weight 120A, the elastic deformation portions 130A, the movable electrode unit 140, and the fixed electrode unit 150 in the plan view.

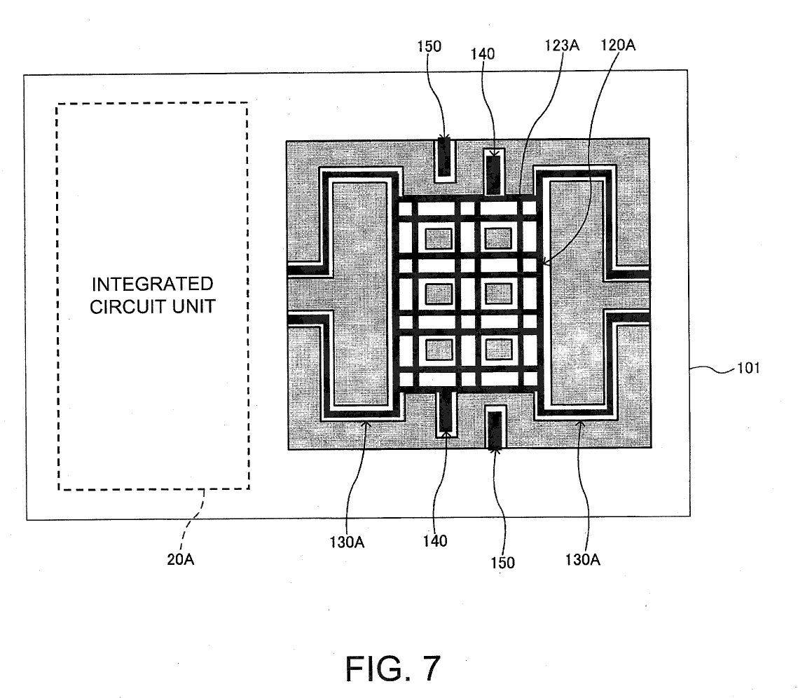

FIG. 7 illustrates a step for producing the first plug 123A. The step for producing the first plug 123A is performed simultaneously with a gate contact step for the integrated circuit unit 20A. According to this embodiment, material such as NSG, BPSG, SOG, and TEOS having film thickness of 10000 to 20000 A is produced by CVD after the step shown in FIG. 6 to form the first between-layers insulation layer 122A. Then, the pattern of the first between-layers insulation layer 122A is etched by a photolithography step to form a predetermined embedding groove pattern into which the first plug 123A is embedded. Then, material such as W, TiW, and TiN is embedded into the embedding groove pattern by sputtering, CVD or other methods. Subsequently, the conductive layer material lying on the first between-layers insulation layer 122A is removed by etching-back or other methods to complete the first plug 123A shown in FIG. 7. The first plug 123A is provided on an area narrower than the contour shape of the movable weight 120A, the elastic deformation portions 130A, the movable electrode unit 140, and the fixed electrode unit 150 in the plan view. The first plug 123A may be smoothed by CMP (chemical mechanical polishing) process.

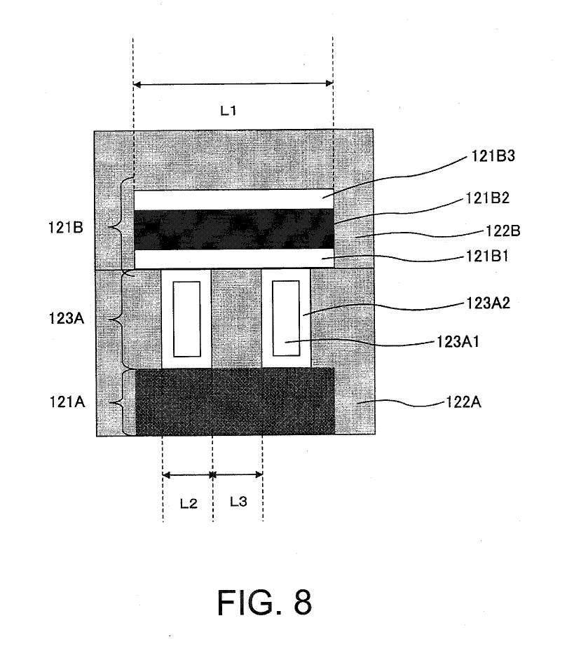

According to comparison between the conductive patterns shown in FIG. 6 and FIG. 7 with respect to the area of the movable weight 120A, for example, the structure shown in FIG. 6 has a single grid pattern, while the structure shown in FIG. 7 has a double grid pattern. More specifically, as illustrated in a cross-sectional view in FIG. 8, two pieces of the first plug 123A each of which has a width L2 (such as 0.5 μm) are provided with a clearance L3 (such as 0.5 μm) therebetween for the first conductive layer 121A having a width L1 (such as 2 μm).

FIG. 8 also shows an example of the first plug 123A. A contact plug 123A1 can be made of material such as W, Cu, and Al, and a barrier film 123A2 covering the periphery of the contact plug 123A1 can be made of material such as Ti and TiN. The contact plug 123A1 having film thickness of 5000 to 10000 A can be formed by sputtering or CVD. The barrier layer 123A2 having film thickness of 100 to 1000 A can be similarly formed by sputtering or CVD.

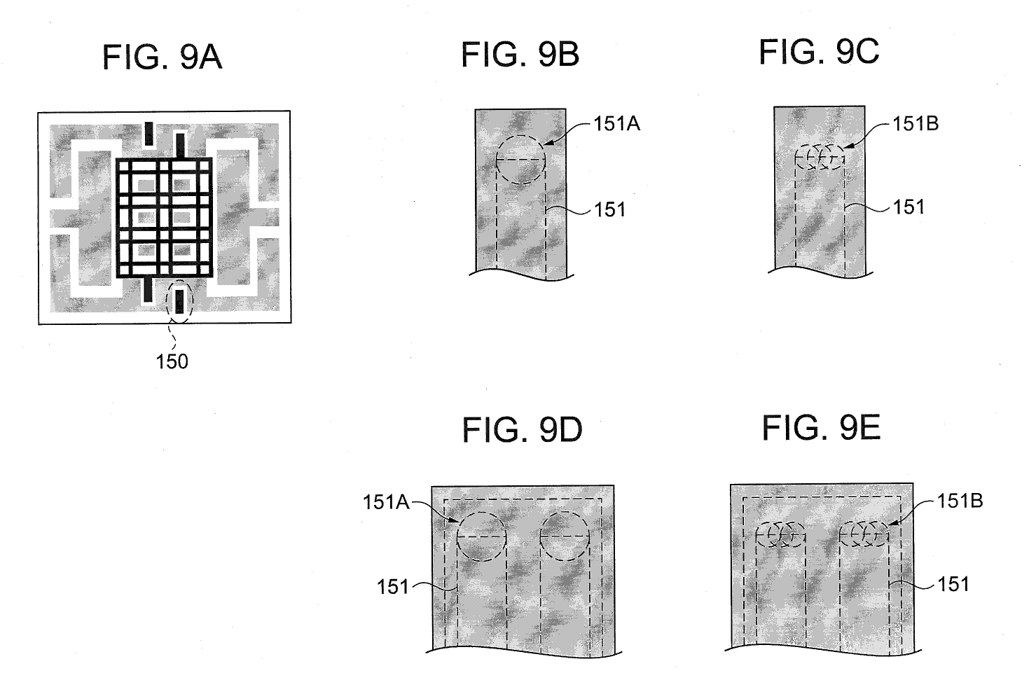

The method of easily embedding particularly the ends of the first plug 123A is now explained with reference to FIGS. 9A through 9E. FIGS. 9B through 9E show examples of the embedding groove pattern into which the fixed electrode unit 150 shown in FIG. 9A are embedded, for example. According to the examples illustrated in FIGS. 9B and 9D, one or two embedding groove patterns 151 formed on the first conductive layer 121A have ends each of which has a single circular arc 151A. On the other hand, according to the examples illustrated in FIGS. 9C and 9E, the one or two embedding groove patterns 151 formed on the first conductive layer 121A have an end each of which has plural circular arcs 151B. By providing not an angular end but a circular arc end for the embedding groove pattern 151, tungsten W or the like can be easily embedded. The plug materials, the plug embedding pattern shapes of the second and third plugs 123B and 123C may be similar to those of the first plug 123A.

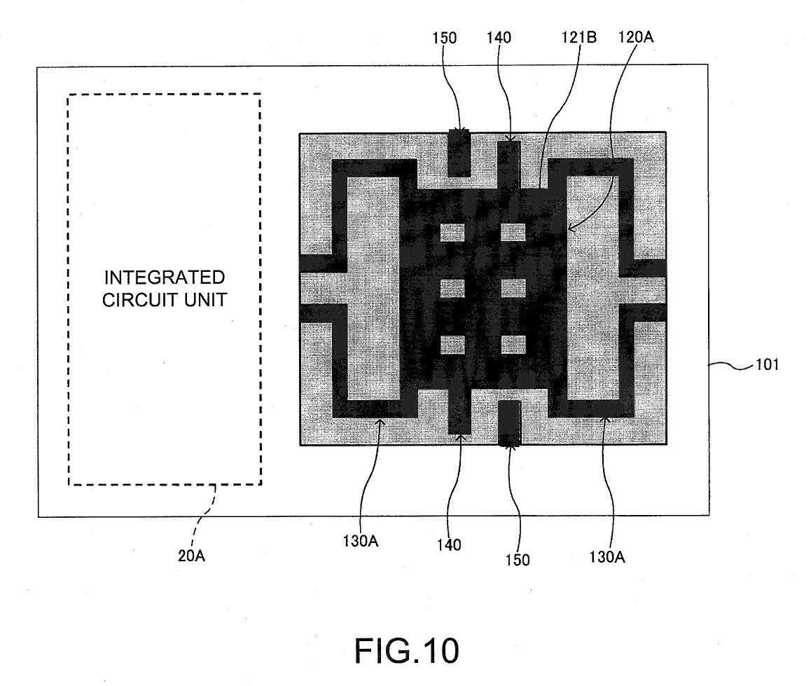

FIG. 10 illustrates a step for producing the second conductive layer 121B. The step for forming the second conductive layer 121B is performed simultaneously with a step for producing a first metal wiring layer of the integrated circuit unit 20A. The formation pattern of the second conductive layer 121B is substantially same as the formation pattern of the first conductive layer 121A shown in FIG. 6. As illustrated in FIG. 8, the second conductive layer 121B may have multilayer structure including a barrier layer 121B1 made of material such as Ti, TiN, TiW, TaN, WN, VN, ZrN, and NbN, a metal layer 121B2 made of material such as Al, Cu, Al alloy, Mo, Ti, and Pt, and an anti-reflection layer 121B3 made of material such as TiN, Ti, and non-crystal Si. The third and fourth conductive layers 121C and 121D can be made of materials similar to that of the second conductive layer 121B. The barrier layer 122B1 having film thickness of 100 to 1000 A can be formed by sputtering. The metal layer 121B2 having film thickness of 5000 to 10000 A can be produced by vacuum deposition or CVD. The anti-reflection layer 121B3 having film thickness of 100 to 1000 A can be formed by sputtering or CVD.

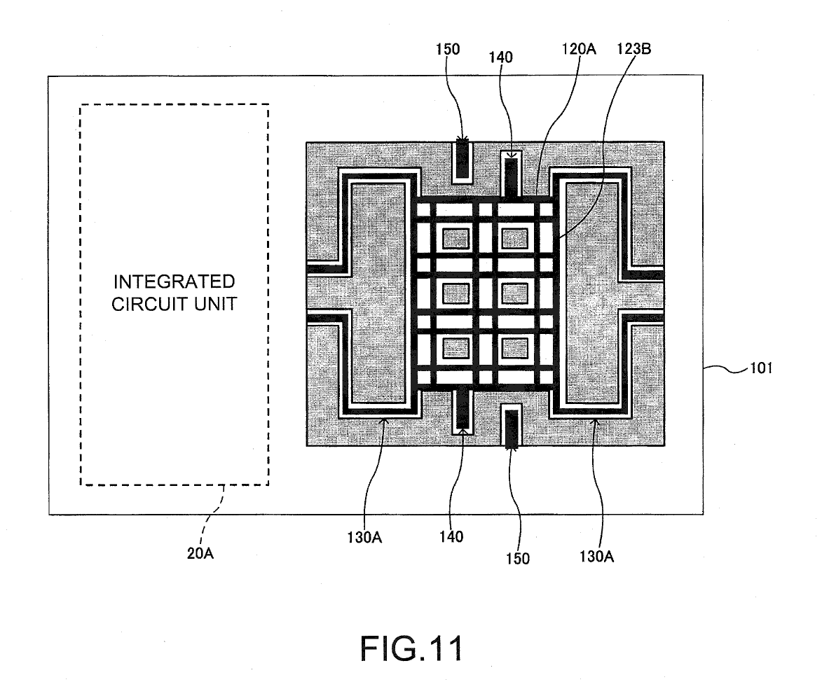

FIG. 11 illustrates a step for producing the second plug 123B. The step for forming the second plug 123B is performed simultaneously with a contact step for the second conductive layer 121B of the integrated circuit unit 20A. The second between-layers insulation layer 122B is produced by a method similar to that for producing the first between-layers insulation layer 122A after the step shown in FIG. 10. Then, the pattern of the second between-layers insulation layer 122B is etched by a photolithography step to form a predetermined embedding groove pattern into which the second plug 123B is embedded. Then, material same as that of the first plug 123A is embedded into the embedding groove pattern by sputtering, CVD or other methods. Subsequently, the conductive layer material lying on the second between-layers insulation layer 122B is removed by etching-back or other methods to complete the second plug 123B shown in FIG. 11. The plan pattern of the second plug 123B is substantially same as the plan pattern of the first plug 123A shown in FIG. 7. The second plug 123B may be smoothed by CMP (chemical mechanical polishing) process.

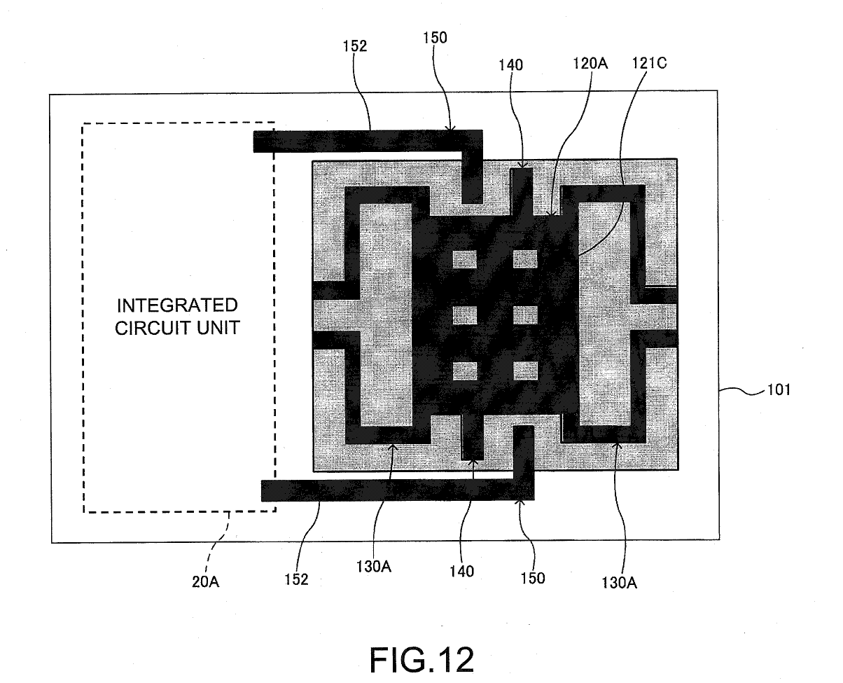

FIG. 12 shows a step for producing the third conductive layer 121C. The step for forming the third conductive layer 121C is performed simultaneously with a step for producing a second metal wiring layer of the integrated circuit unit 20A. The formation pattern of the third conductive layer 121C is substantially same as the formation patterns of the first and second conductive layers 121A and 121B shown in FIGS. 6 and 10. According to this embodiment, the third conductive layer 121C has a wiring pattern 152 extended from an area corresponding to the fixed electrode unit 150 toward an area corresponding to the fixed frame 110 to be connected with the integrated circuit unit 20A by wiring as illustrated in FIG. 12.

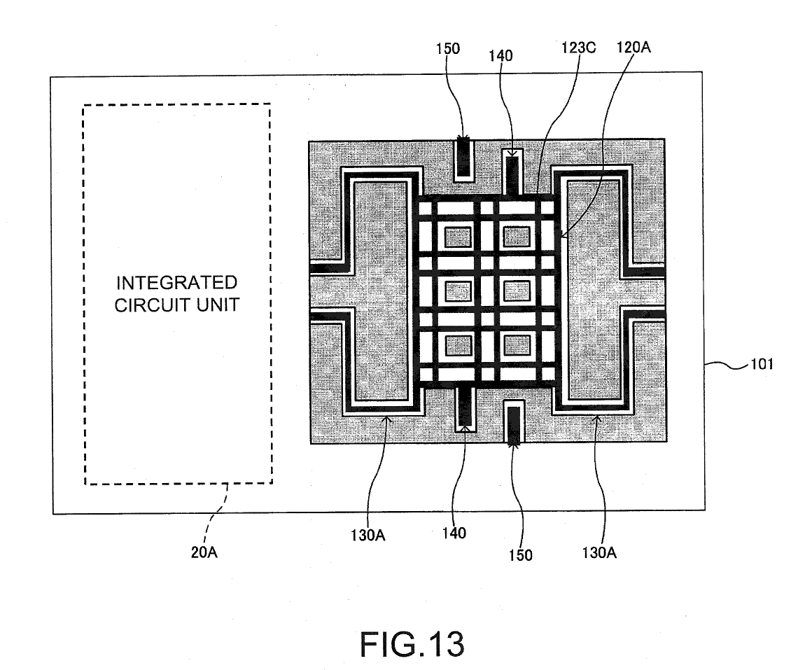

FIG. 13 shows a step for producing the third plug 123C. The step for forming the third plug 123C is performed simultaneously with a contact step for the third conductive layer 121C of the integrated circuit unit 20A. The third between-layers insulation layer 122C is produced by a method similar to those for producing the first and second between-layers insulation layers 122A and 122B after the step shown in FIG. 12. Then, the pattern of the third between-layers insulation layer 122C is etched by a photolithography step to form a predetermined embedding groove pattern into which the third plug 123C is embedded. Then, material same as those of the first and second plugs 123A and 123B is embedded into the embedding groove pattern by sputtering, CVD or other methods. Subsequently, the conductive layer material lying on the third between-layers insulation layer 122C is removed by etching-back or other methods to complete the third plug 123C shown in FIG. 13. The plan pattern of the third plug 123C is substantially same as the plan patterns of the first and second plugs 123A and 123B shown in FIGS. 7 and 11. The third plug 123C may be smoothed by CMP (chemical mechanical polishing) process.

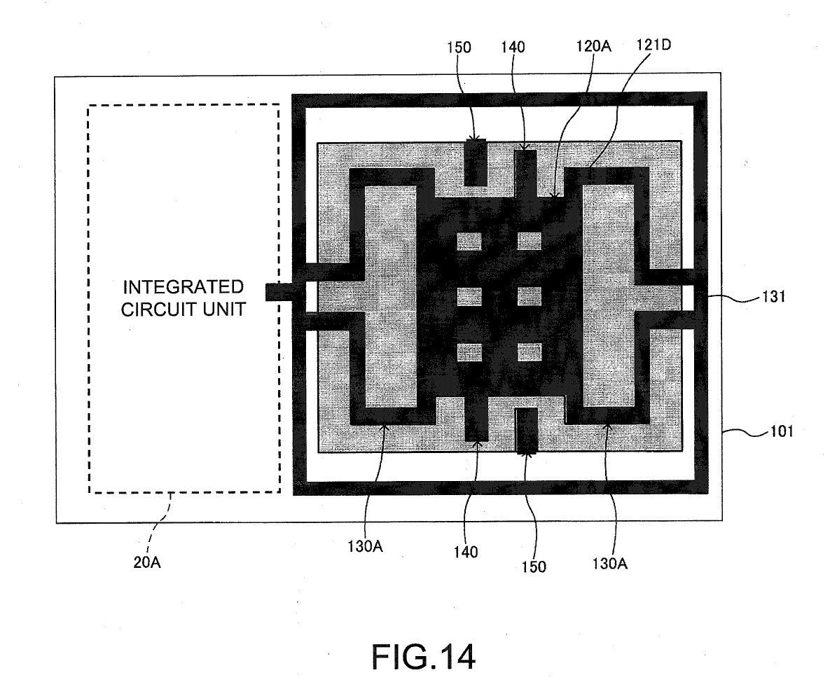

FIG. 14 shows a step for producing the fourth conductive layer 121D. The step for forming the fourth conductive layer 121D is performed simultaneously with a step for producing a third metal wiring layer of the integrated circuit unit 20A. The formation pattern of the fourth conductive layer 121D is substantially same as the formation patterns of the first and second conductive layers 121A and 121B shown in FIGS. 6 and 10 on an area corresponding to the movable weight 120A, the movable electrode unit 140, and the fixed electrode unit 150. According to this embodiment, the fourth conductive layer 121D has a ring-shaped wiring pattern 131 extended from an area corresponding to the elastic deformation portions 130A toward an area corresponding to the fixed frame 110 to be connected with the integrated circuit unit 20A by wiring as illustrated in FIG. 14. By this method, the movable electrode unit 140 can be connected with the wiring pattern 131 via the conductive layers 121A through 121D and the plugs 123A through 123C of the movable weight 120A and the elastic deformation portions 130A to be connected with the integrated circuit unit 20A.

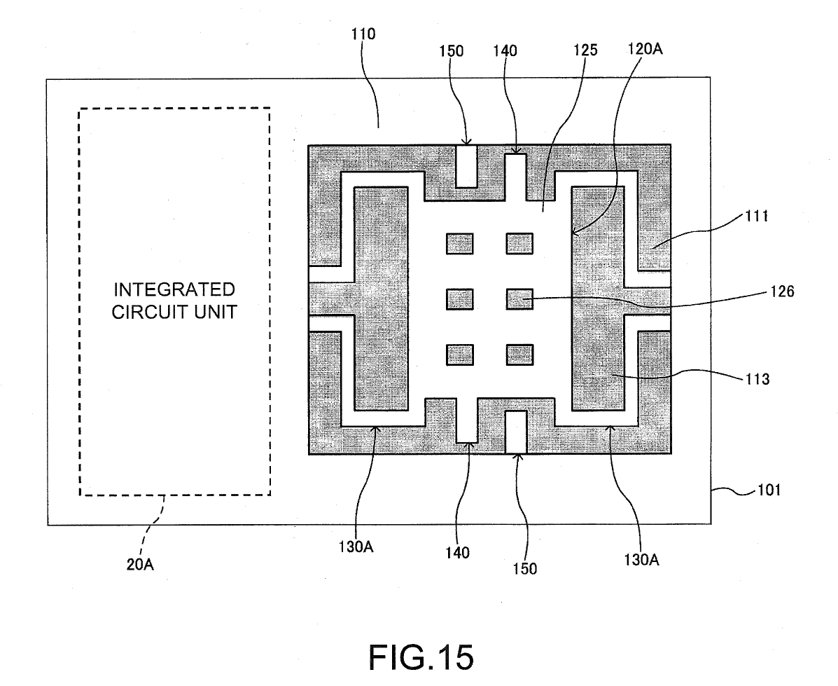

FIG. 15 shows a step for producing the protection layer 125. The protection layer 125 is coated on the entire surface by applying PSiN, SiN, SiO₂, or the like having film thickness of 5000 to 20000 A by CVD to the surface. Then, the pattern of the protection layer 125 is etched by the etching step shown in FIG. 5B. Also, the cavity portion 111, the cavity portions 113, and the through hole 126 are simultaneously formed.

### 2. Second Embodiment

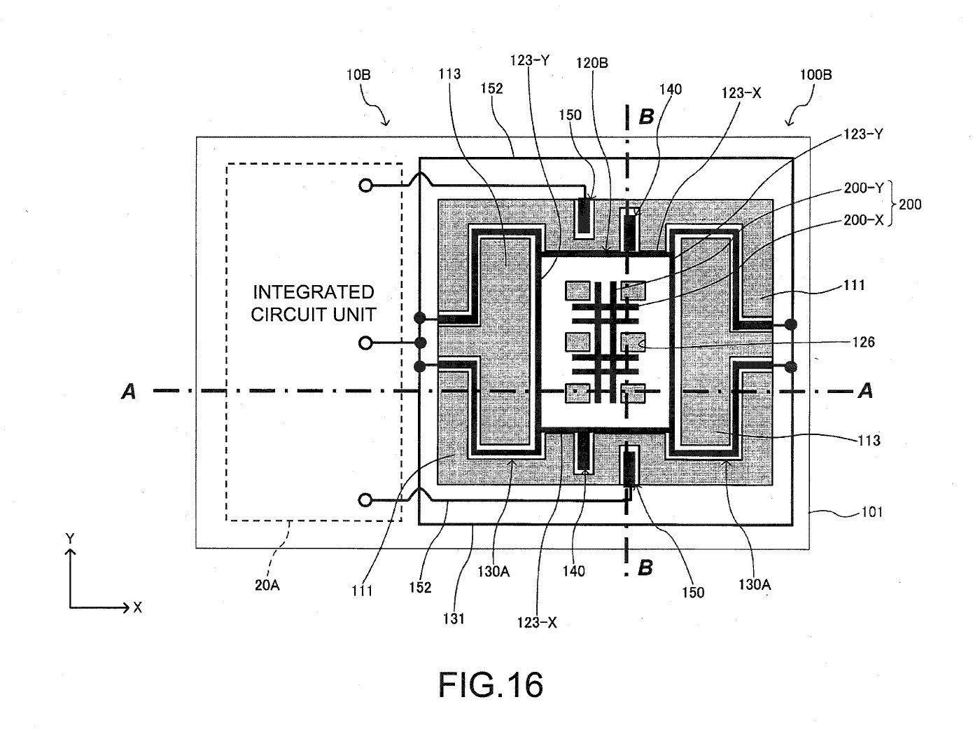

A second embodiment according to the invention is now described with reference to FIGS. 16 through 18. In the following explanation, only the points of the second embodiment different from the first embodiment are touched upon. According to an acceleration sensor module 10B in the second embodiment, an acceleration sensor 100B in this embodiment has a movable weight 120B different from the movable weight 120A of the acceleration sensor 100A in the first embodiment.

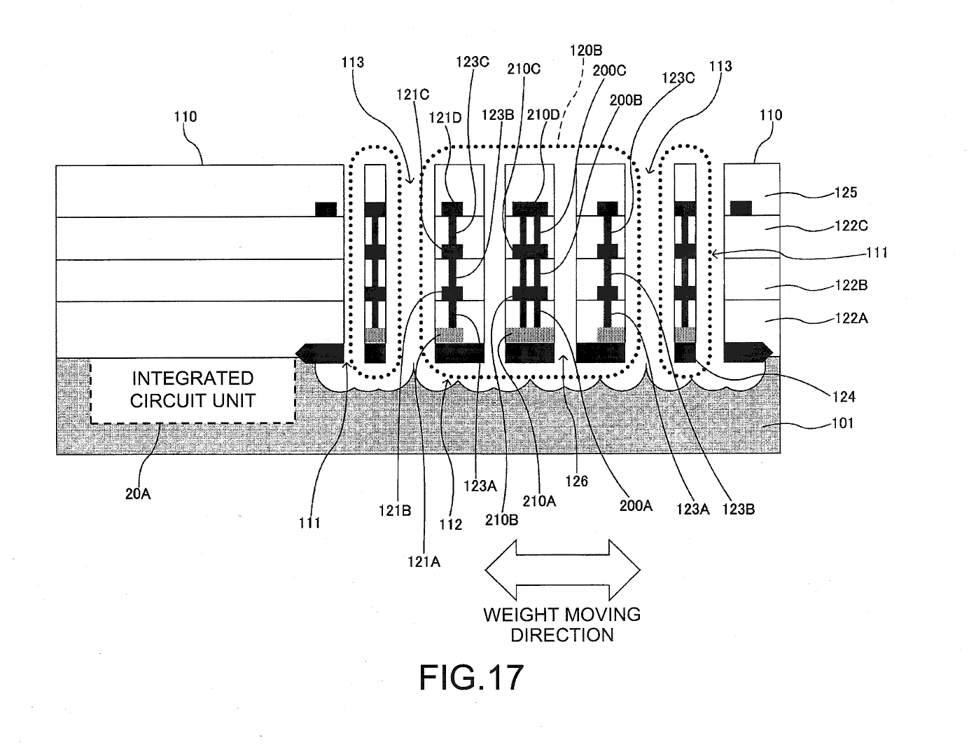

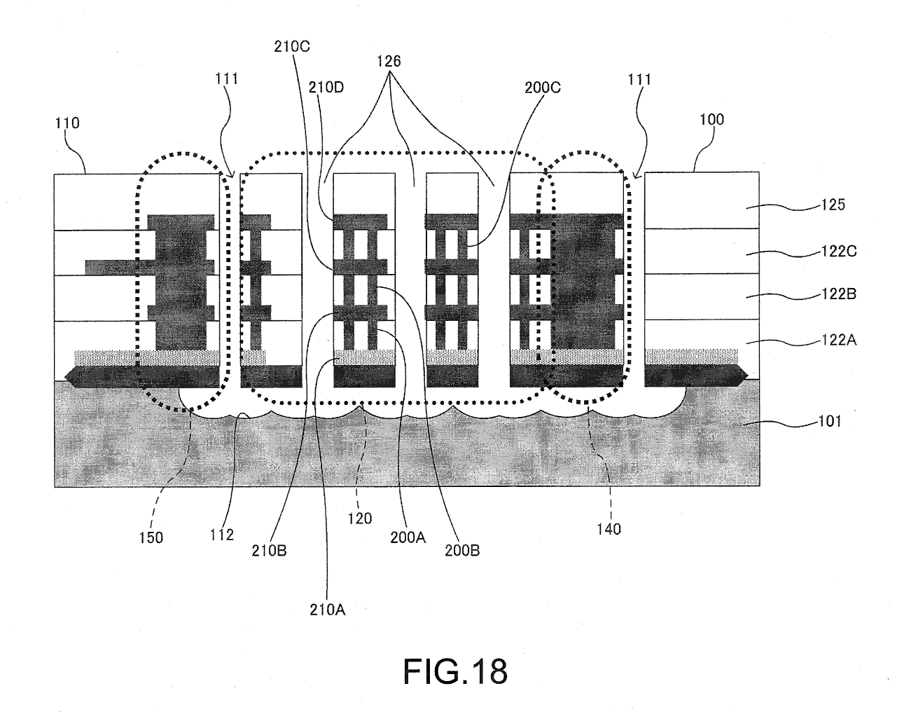

The acceleration sensor 100B has the ring-shaped first plugs 123-X and 123-Y disposed on the movable weight 120B and connected with the movable electrode unit 140 similarly to the acceleration sensor 100A in the first embodiment. However, the second embodiment is different from the first embodiment in that a second plug 200 having a grid pattern is electrically floating. The second plug 200 in the grid pattern shape includes plugs 200A through 200C formed on the respective layers (see FIGS. 17 and 18). Each of the plugs 200A through 200C has a plug 200-X extending in wall shape in the X direction as the longitudinal direction (see FIG. 16), and a plug 200-Y extending in wall shape in the Y direction as the longitudinal direction (see FIG. 16). In addition, the second embodiment is different from the first embodiment in that conductive layers 210A through 210D connected with one another by the second plug 200 (200A through 200C) (see FIGS. 17 and 18) are also electrically floating.

According to the first embodiment, all the potentials of the respective wiring layers of the movable weight 120A (conductive layers 121A through 121D and the plugs 123A through 123C) are equalized. According to the second embodiment, however, the potentials of the wiring layers within the movable weight 120B are separated. More specifically, the first plugs 123A through 123C and the conductive layers 121A through 121D connected via the first plugs 123A through 123C are used as wires for the movable electrode unit 140. On the other hand, the second plug 200 (200A through 200C) and the conductive layers 210A through 210D disposed on the respective layers and connected with one another via the second plug 200 are electrically insulated in the floating condition such that these layers 210A through 210D and plug 200 only function as weight. By this method, the movable weight 120B can reduce stray capacity produced between the movable weight 120B and the silicon substrate 101 and the like while maintaining the weight mass.

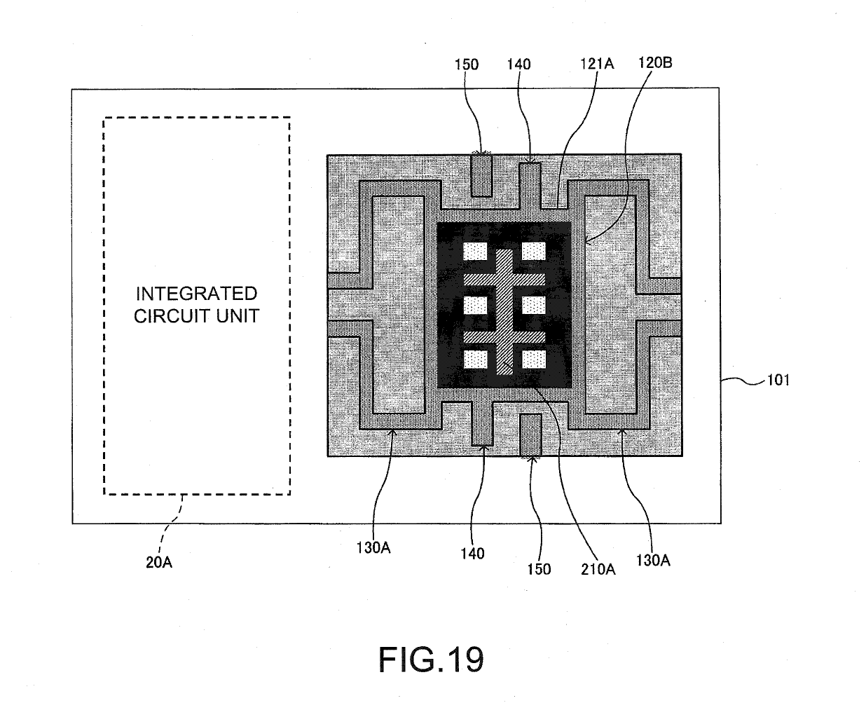

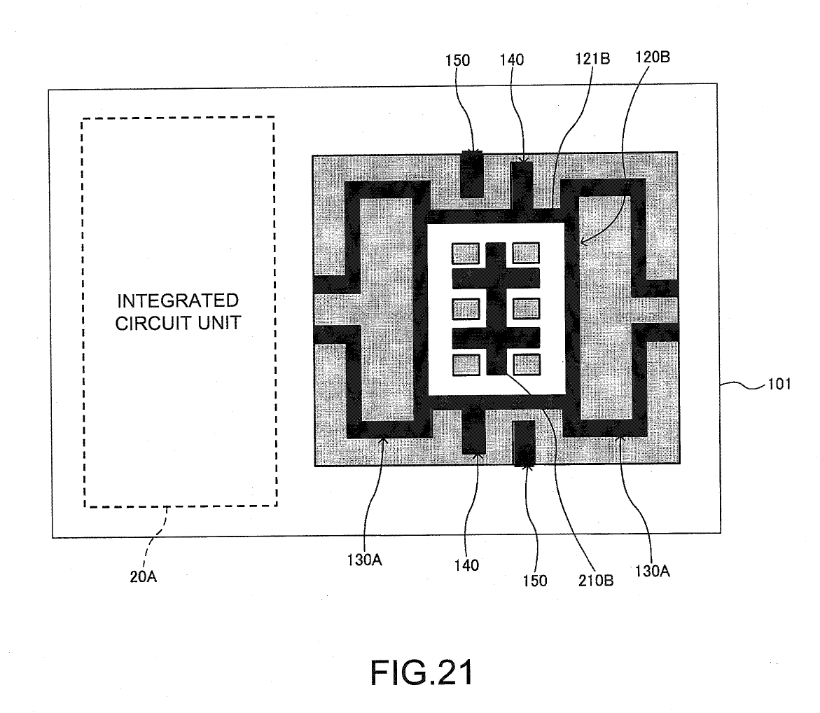

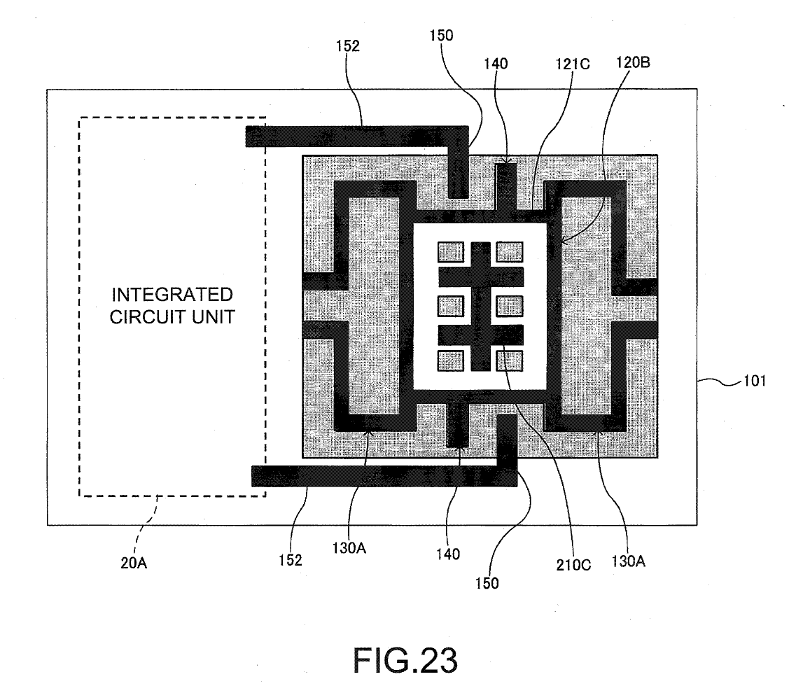

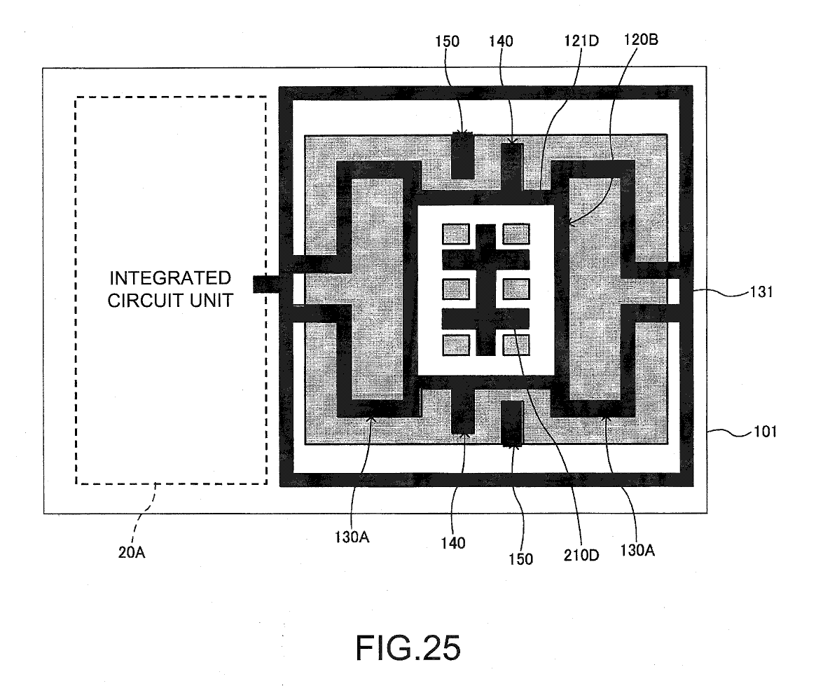

FIGS. 19 through 25 illustrate the plugs or the conductive layers on the respective layers corresponding to FIGS. 6, 7, and 10 through 14. In FIG. 19 (first layer: lowest layer polysilicon), FIG. 21 (second layer: first metal wiring layer), FIG. 23 (third layer: second metal wiring layer), and FIG. 25 (fourth layer: third metal wiring layer) showing the conductive layers on the respective layers, the movable weight 120B has the electrically isolated second conductive layers 210A through 210D separately from the first conductive layers 121A through 121D connected with the movable electrode unit 140.

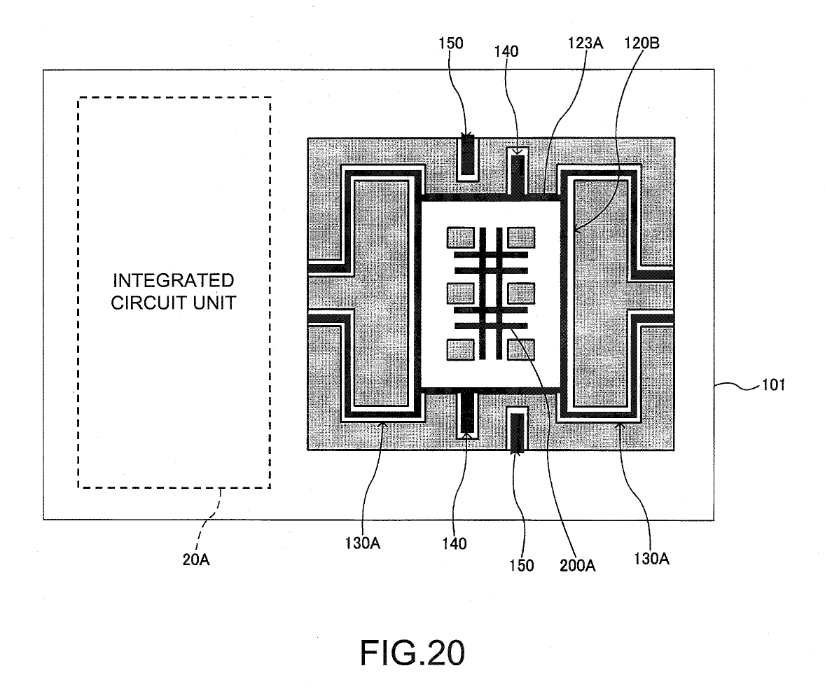

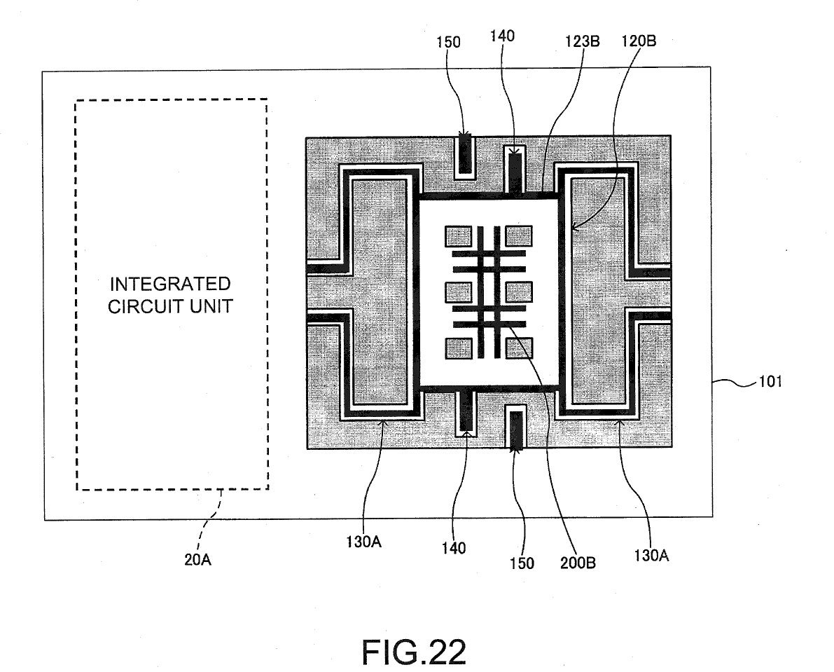

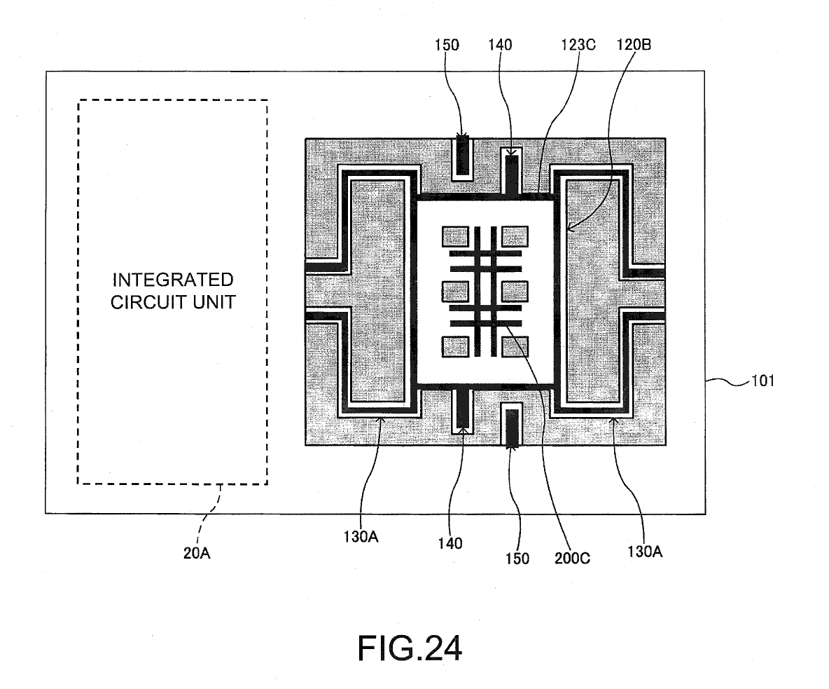

In FIG. 20 (between the first and second layers), FIG. 22 (between the second and third layers), and FIG. 24 (between the third and fourth layers) showing the plugs on the respective layers, the movable weight 120B has the electrically isolated second plugs 200A through 200C separately from the first plugs 123A through 123C connected with the movable electrode unit 140.

### 3. Third Embodiment

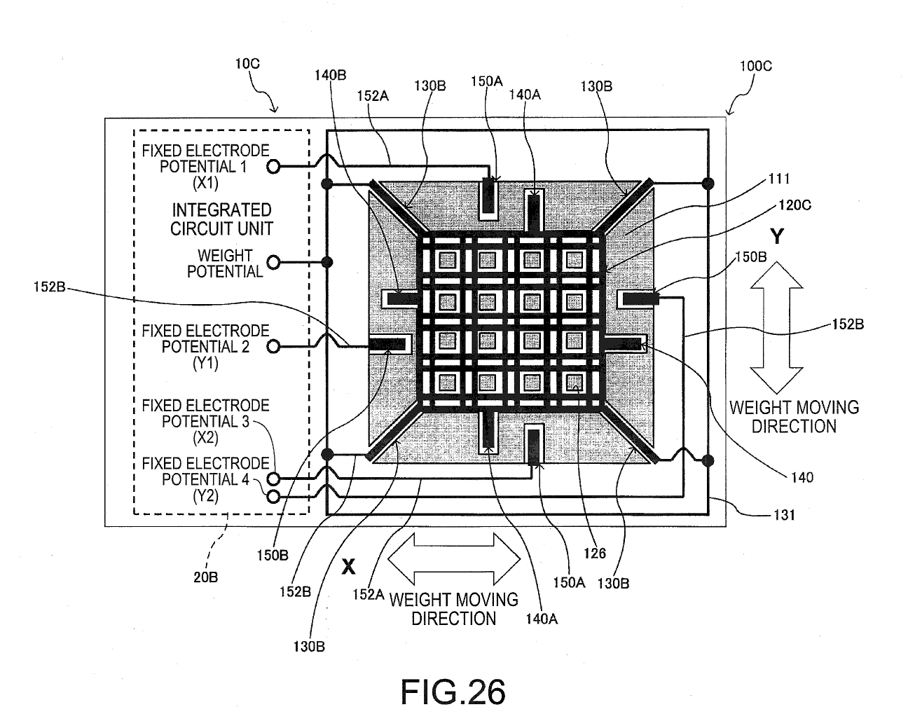

A biaxial capacitive acceleration sensor according to a third embodiment of the invention is now described with reference to FIGS. 26 through 33. In the following explanation, only the points of the third embodiment different from the first embodiment are touched upon. As illustrated in FIG. 26, an acceleration sensor 100C of an acceleration sensor module 10C includes four movable electrode units 140 projecting from the four sides of a movable weight 120C having a quadrangular contour, and the four fixed electrode units 150 paired with the four movable electrode units 140 for detecting acceleration in biaxial directions.

An integrated circuit unit 20B connected with the acceleration sensor 100C receives a common weight potential connected with the two movable electrode units 140A for the X axis detection and the two movable electrode units 140B for the Y axis detection, and further receives four fixed electrode potentials 1 through 4 from the two fixed electrode units 150A for the X axis detection and the two fixed electrode units 150B for the Y axis detection separately from one another. The integrated circuit unit 20B having two pairs of the detection circuits shown in FIG. 4 corresponding to the X axis and the Y axis can separately detect acceleration for each of the X and Y axes.

Since the movable electrode units 140A and 140B project from the four sides of the movable weight 120C, elastic deformation portions 130B extend along diagonal lines extended from the corners of the movable weight 120C having a quadrangular contour. In case of the elastic deformation portions 130B having this structure, the cavity portions 113 shown in FIG. 1 are not required.

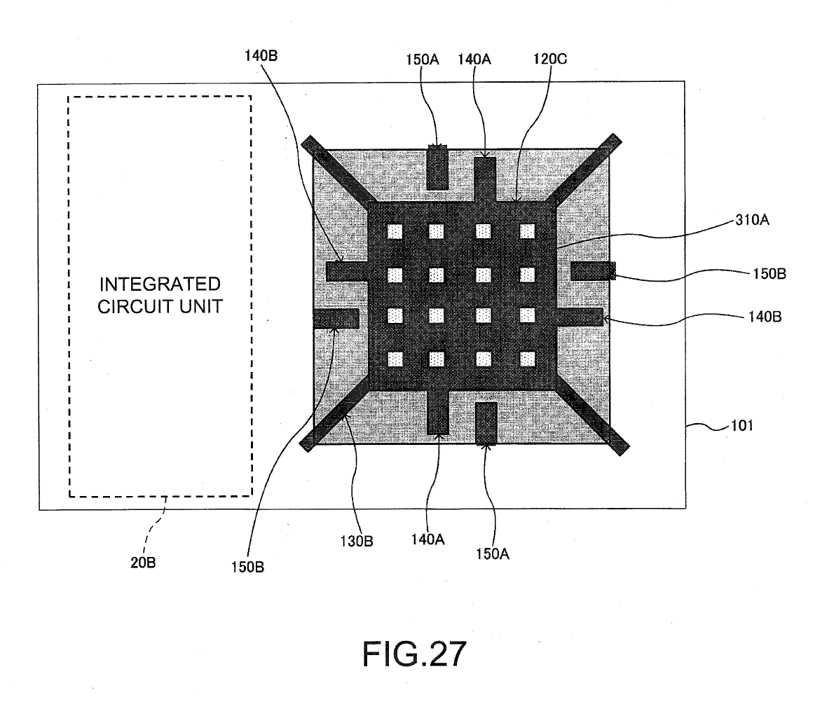

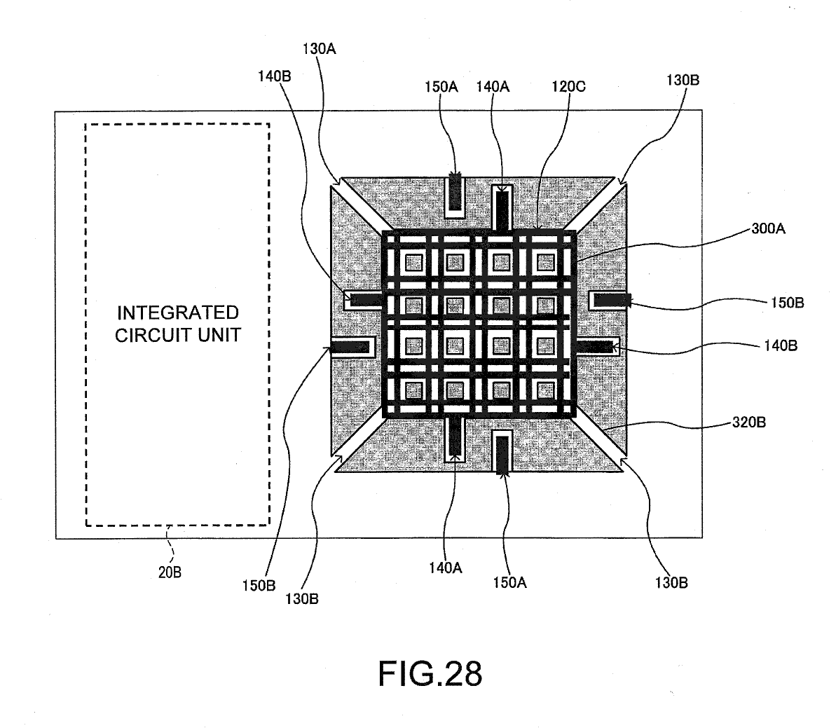

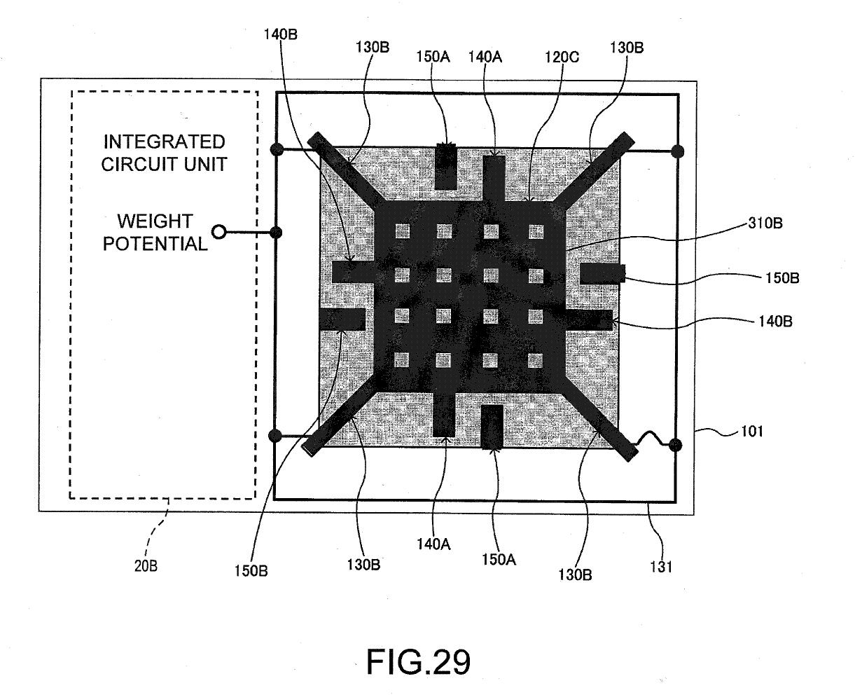

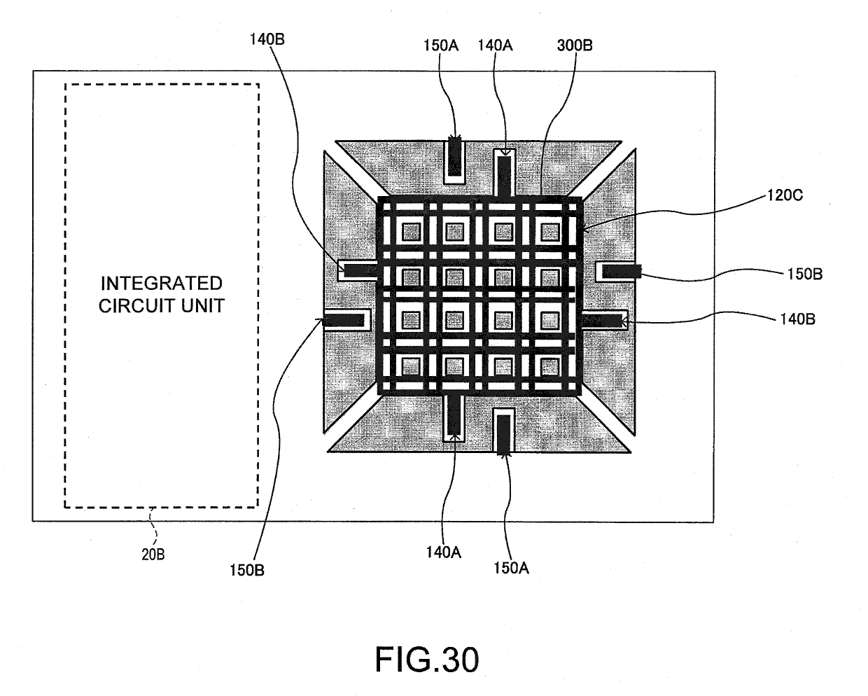

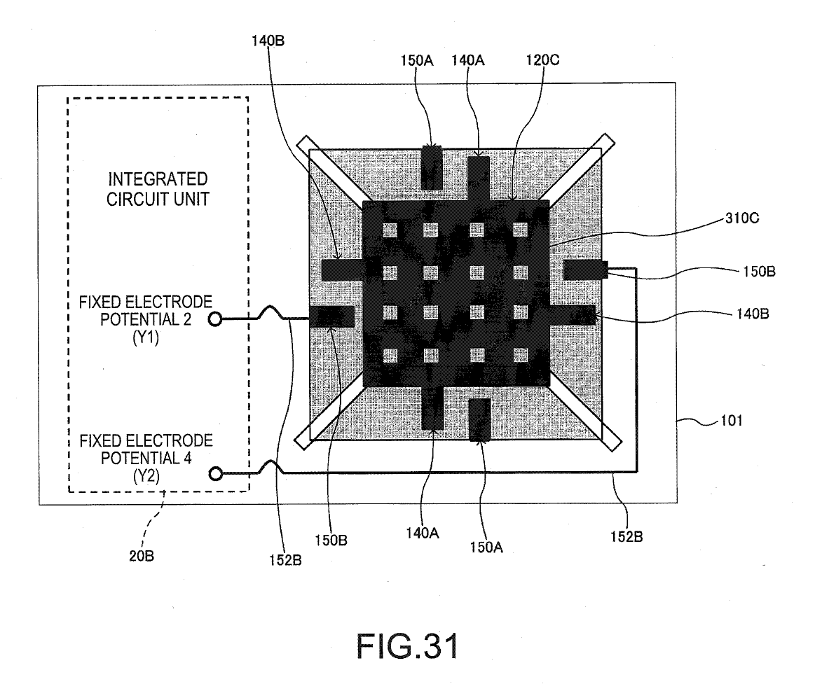

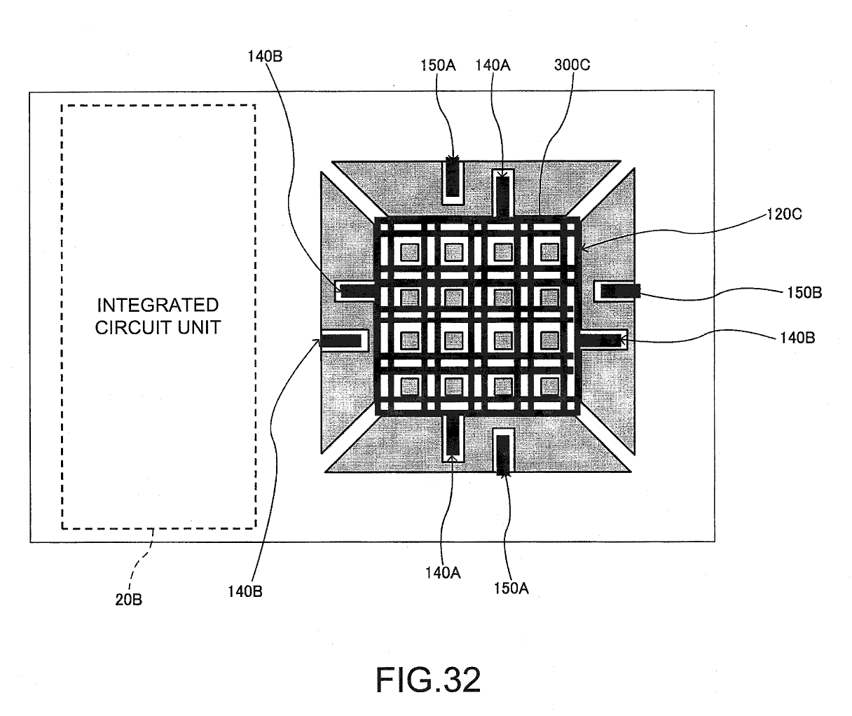

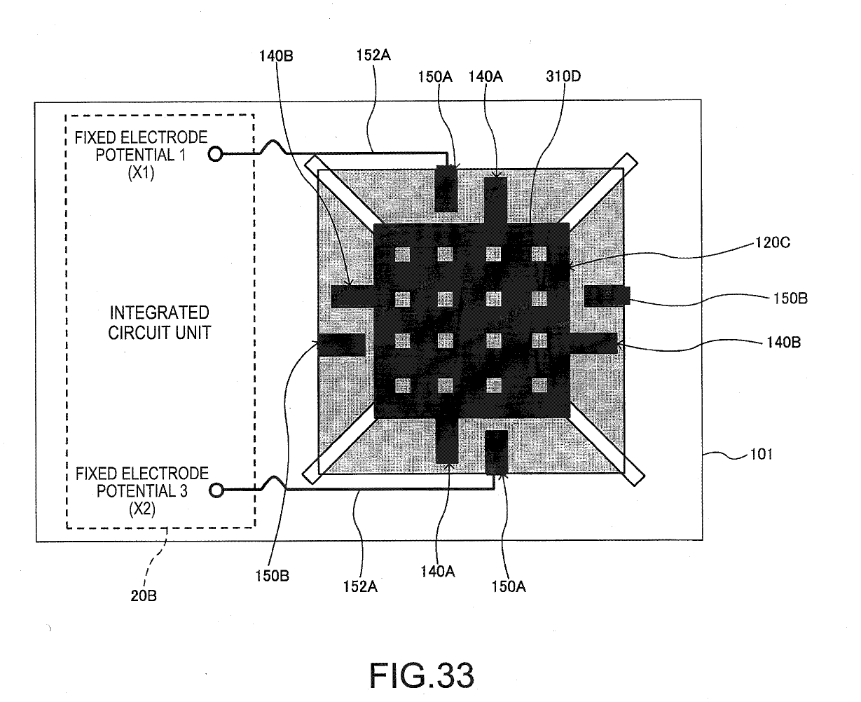

FIGS. 27 through 33 illustrate the plugs or the conductive layers on the respective layers corresponding to FIGS. 6, 7, and 10 through 14. In FIG. 27 (first layer: lowest layer polysilicon), FIG. 29 (second layer: first metal wiring layer), FIG. 31 (third layer: second metal wiring layer), and FIG. 33 (fourth layer: third metal wiring layer) showing the conductive layers on the respective layers, the movable weight 120C has conductive layers 310A through 310D in the grid pattern shape connected with the movable electrode unit 140A and the movable electrode unit 140B. In FIG. 28 (between the first and second layers), FIG. 30 (between the second and third layers), and FIG. 32 (between the third and fourth layers) showing the plugs on the respective layers, the movable weight 120C has plugs 300A through 300C in the grid pattern shape connected with the movable electrode units 140A and 140B.

The third embodiment is same as the first embodiment in that the movable weight 120C, the movable electrode units 140A and 140B, and the fixed electrode units 150A and 150B have the plural conductive layers and the plugs connecting the conductive layers. However, drawing wires toward the integrated circuit unit 20B for inputting the four fixed electrode potentials 1 through 4 to the integrated circuit unit 20B from the two fixed electrode units 150A for the X axis detection and the two fixed electrode units 150B for the Y axis detection separately from one another are formed on the different layers. More specifically, a drawing wire 152A extending from the two fixed electrode units 150A for the X axis detection is formed on the same layer as the conductive layer 310D as illustrated in FIG. 33. Also, a drawing wire 152B extending from the two fixed electrode units 150B for the Y axis detection is formed on the same layer as the conductive layer 310C as illustrated in FIG. 31.

In the area of the elastic deformation portions 130B, conductive layers for wiring are provided only on the same layer as the conductive layer 310B shown in FIG. 29, but neither conductive layer nor plug exists on the other layers. This is because the elastic deformation portions 130B having no cavity portion 113 as in the third embodiment increases its elastic deformation force by reducing the conductive layer and the plug. The elastic deformation portions 130B need at least one conductive layer for wiring, but include only a smaller number of conductive layers than that of the conductive layers 310A through 310D formed on the movable weight 120C so as to increase the elastic deformation force of the elastic deformation portions 130B.

### 4. Fourth Embodiment

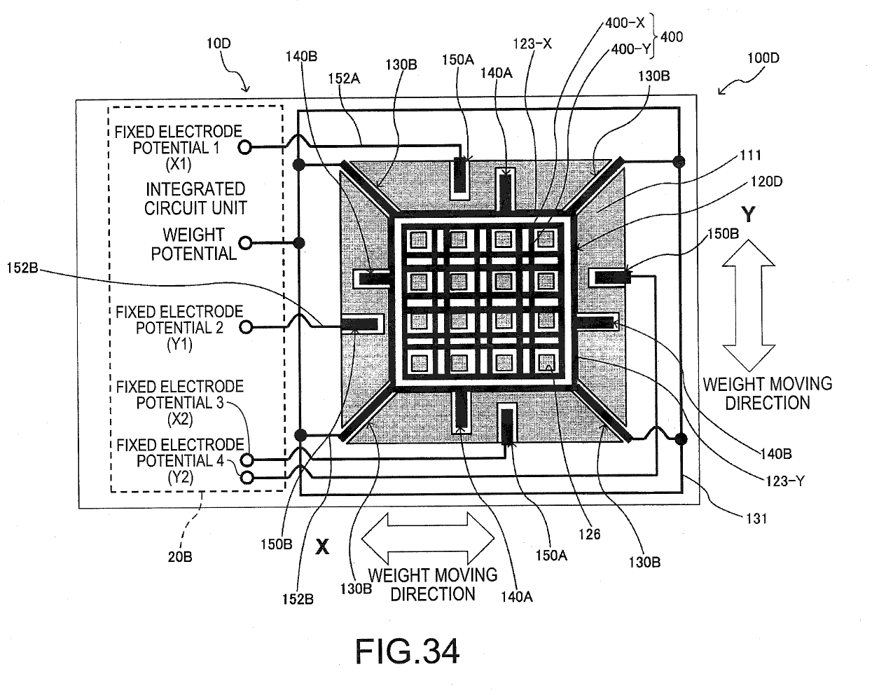

FIG. 34 illustrates a fourth embodiment of the invention. The fourth embodiment applies the technique of the second embodiment (isolated pattern of the movable weight) to the third embodiment. In the following explanation, only the points of the fourth embodiment different from the first and third embodiments are touched upon.

As illustrated in FIG. 34, an acceleration sensor 100D of an acceleration sensor module 10D has the ring-shaped first plugs 123-X and 123-Y disposed on a movable weight 120D and connected with the movable electrode units 140A and 140B similarly to the first and third embodiments. However, the fourth embodiment is different from the first and third embodiments in that a second plug 400 having a grid pattern is electrically floating. The second plug 400 in the grid pattern shape includes a plug 400-X extending in wall shape in the X direction as the longitudinal direction, and a plug 400-Y extending in wall shape in the Y direction as the longitudinal direction. In addition, the fourth embodiment is different from the first and third embodiments in that respective conductive layers (not shown) connected with one another by the second plug 400 are electrically floating.

According to the first and third embodiments, all the potentials of the respective wiring layers of the movable weight 120A (conductive layers 121A through 121D and the plugs 123A through 123C) are equalized. According to the fourth embodiment, however, the potentials of the wiring layers within the movable weight 120D are separated. Particularly, the second plug 400 and the respective conductive layers connected with one another via the second plug 400 are electrically insulated from other parts of the first conductive layers (not shown) and the first plugs 123-X and 123-Y on the movable weight 120D and brought into the floating condition, thereby functioning only as weight. By this method, the movable weight 120D can reduce stray capacity produced between the movable weight 120D and the silicon substrate 101 and the like while maintaining the weight mass.

### 5. Fifth Embodiment

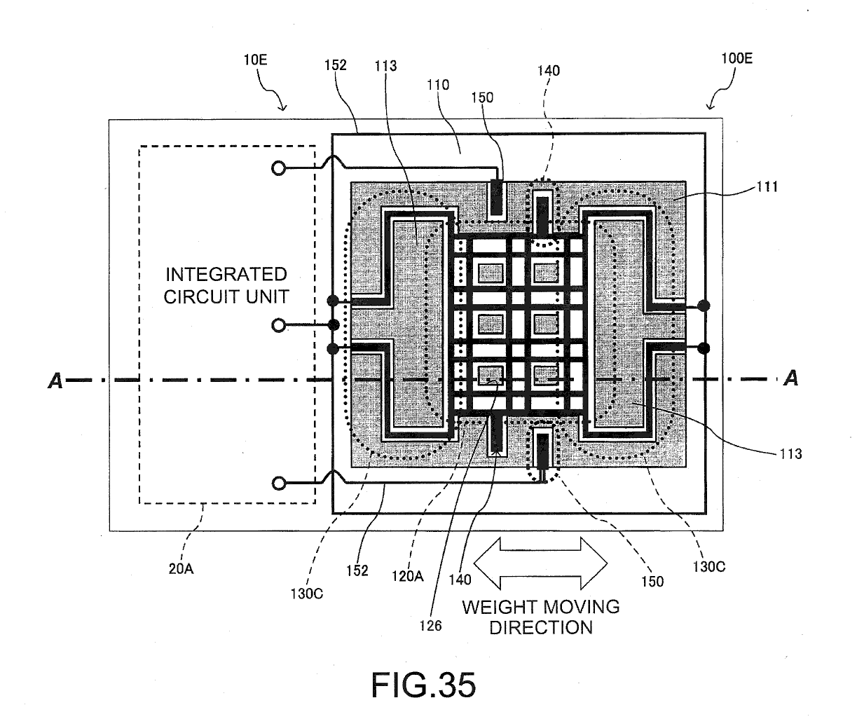

FIG. 35 illustrates a fifth embodiment of the invention. The fifth embodiment applies the technique of the third embodiment (reduction of the wiring layers and the plugs in the elastic deformation portions) to the first embodiment. In the following explanation, only the points of the fifth embodiment different from the first embodiment are touched upon.

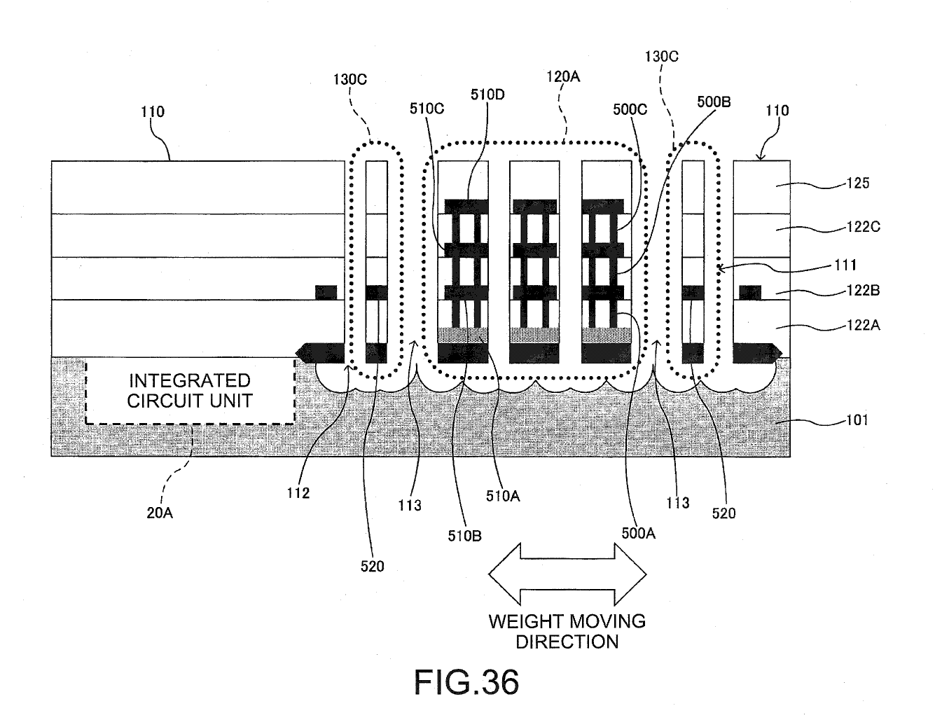

Though an acceleration sensor module 10E shown in FIG. 35 is different from the first embodiment in that an acceleration sensor 100E has elastic deformation portions 130C, FIG. 35 is substantially identical to FIG. 1. However, FIG. 36 as a cross-sectional view taken along a line A-A in FIG. 35 is different from FIG. 2 as a cross-sectional view taken along a line A-A in FIG. 1. The elastic deformation portions 130A shown in FIG. 2 have a vertical cross section including the four conductive layers and the three plugs connecting these conductive layers. However, the elastic deformation portions 130C shown in FIG. 36 include a conductive layer 520 only on the same layer as a conductive layer 520B of the movable weight 120A, and do not have conductive layers nor plugs on the other layers.

Thus, even in the structure including the cavity portions 113 in the elastic deformation portions 130C, the elastic deformation force of the elastic deformation portions 130C can be increased by providing the conductive layers on a smaller number of layers than the plural conductive layers 510A through 510D formed on the movable weight 120A.

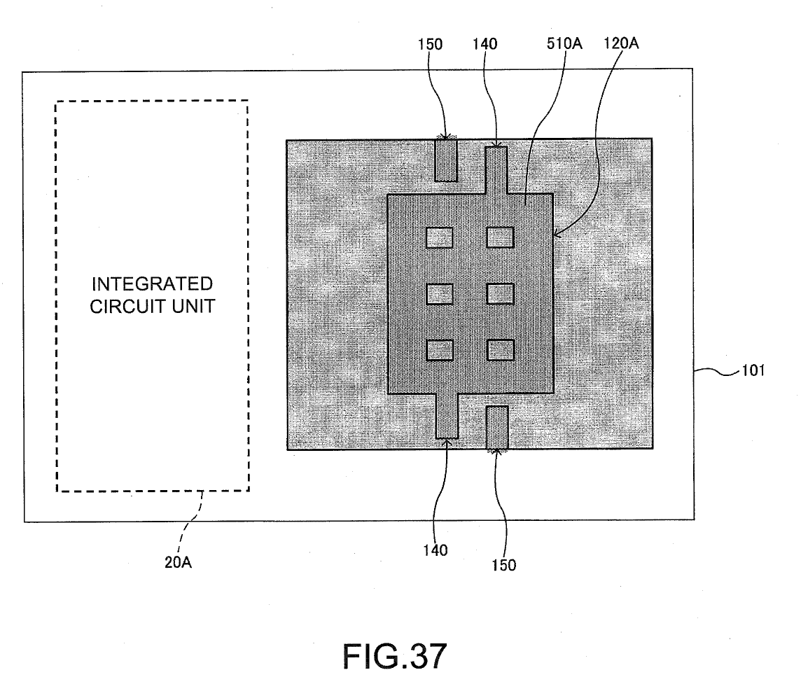

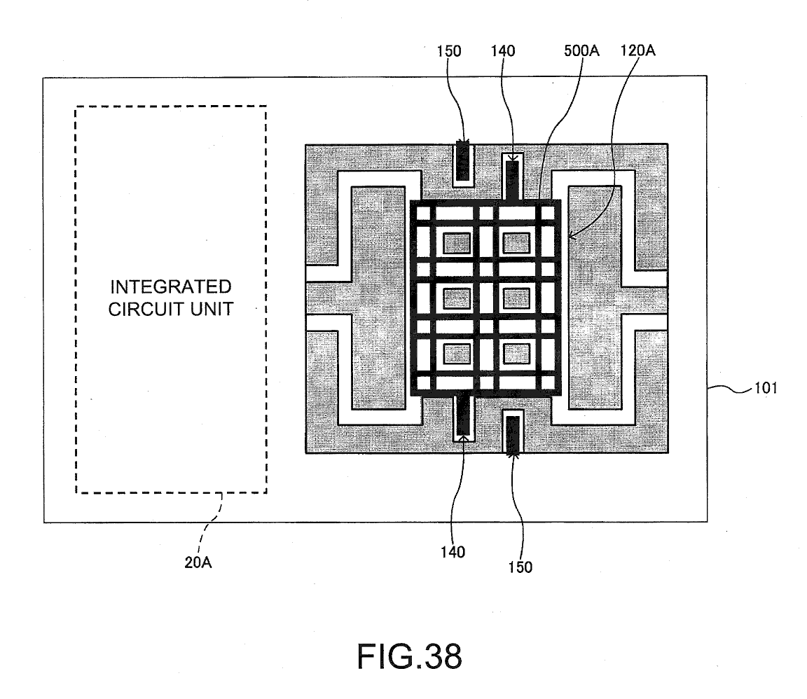

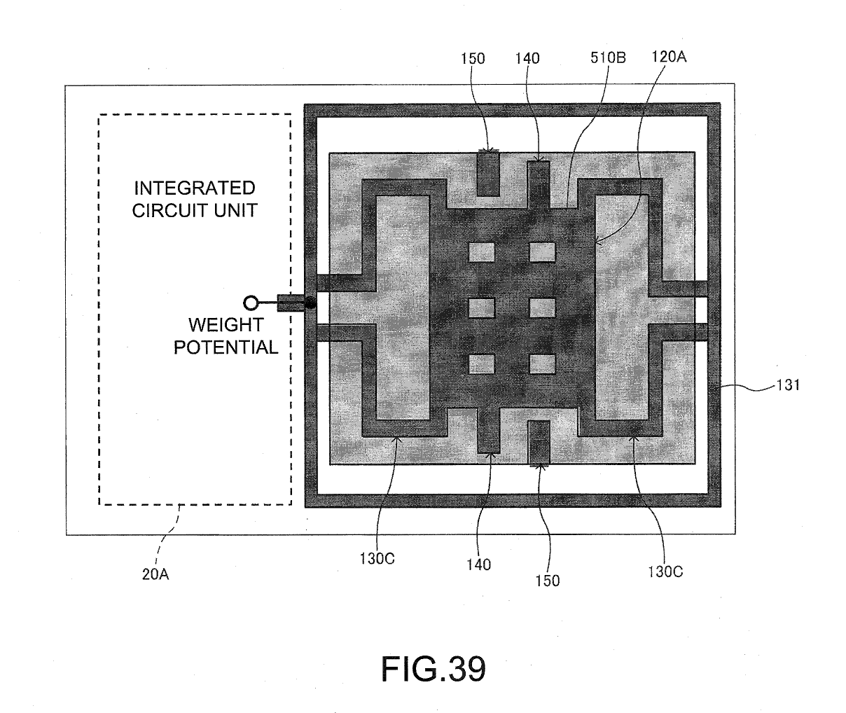

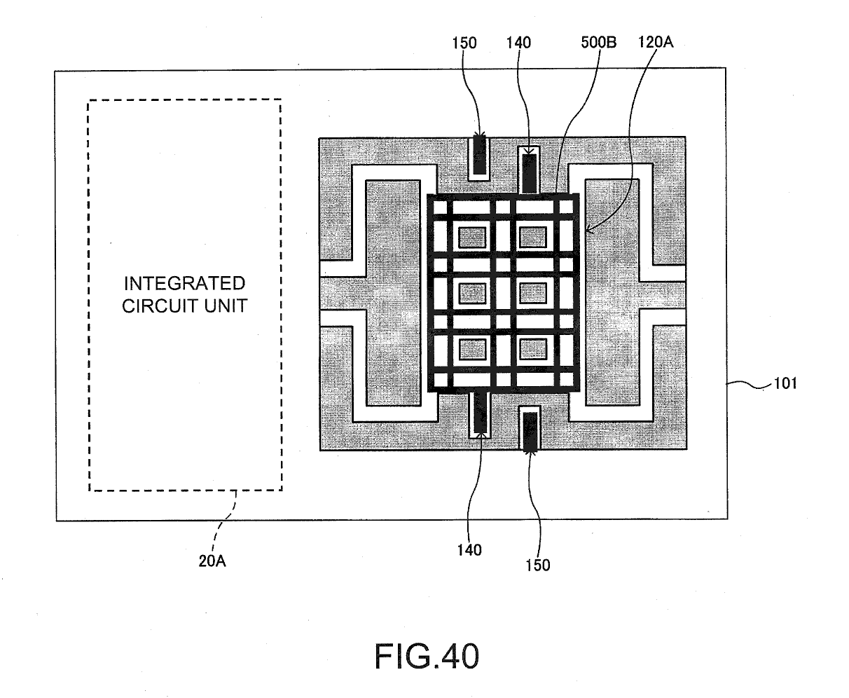

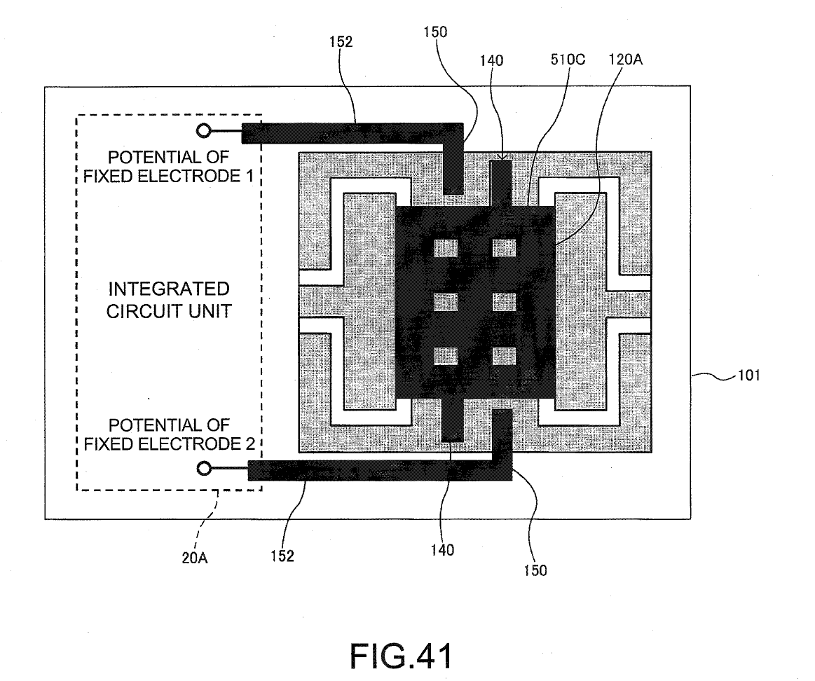

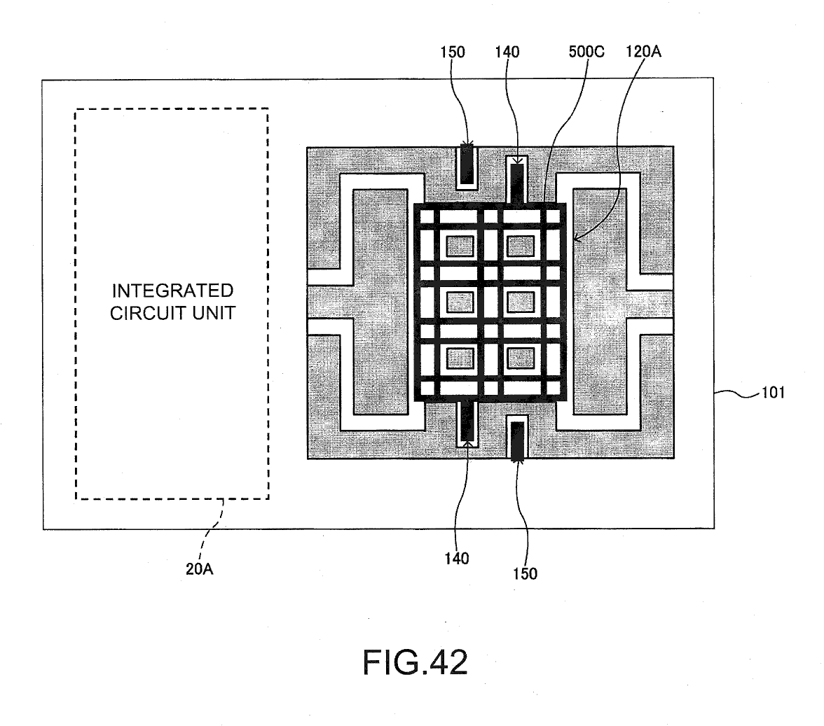

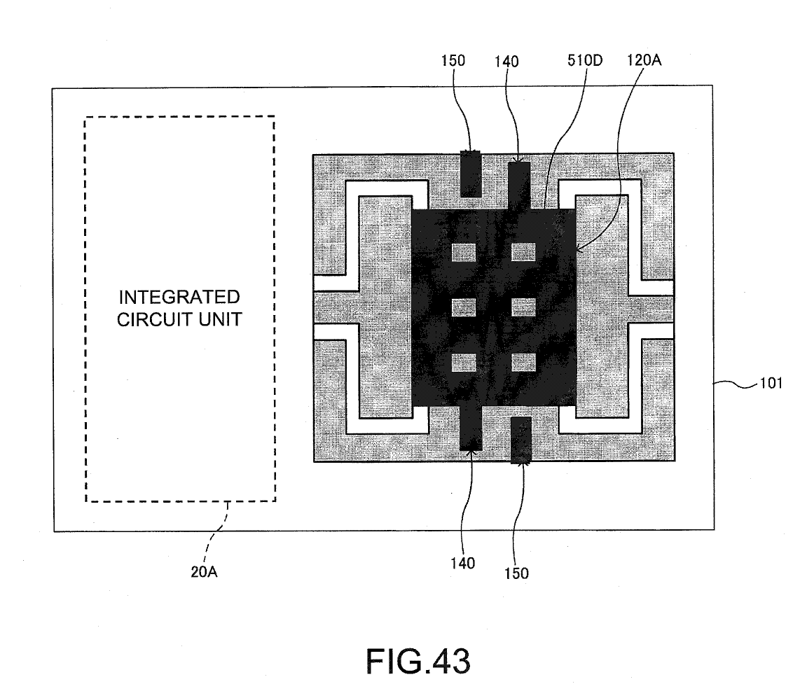

FIGS. 37 through 43 illustrate the plugs or the conductive layers on the respective layers corresponding to FIGS. 6, 7, and 10 through 14 in the first embodiment. In FIG. 37 (first layer: lowest layer polysilicon), FIG. 39 (second layer: first metal wiring layer), FIG. 41 (third layer: second metal wiring layer), and FIG. 43 (fourth layer: third metal wiring layer) showing the conductive layers on the respective layers, the movable weight 120A has the conductive layers 510A through 510D in the grid pattern shape connected with the movable electrode unit 140A and the movable electrode unit 140B. In FIG. 38 (between the first and second layers), FIG. 40 (between the second and third layers), and FIG. 42 (between the third and fourth layers) showing the plugs on the respective layers, the movable weight 120A has plugs 500A through 500C in the grid pattern shape connected with the movable electrode unit 140. As obvious from FIG. 39, the elastic deformation portions 130C have the conductive layer 520 only on the same layer as the conductive layer 520B of the movable weight 120A.

### 6. Sixth Embodiment

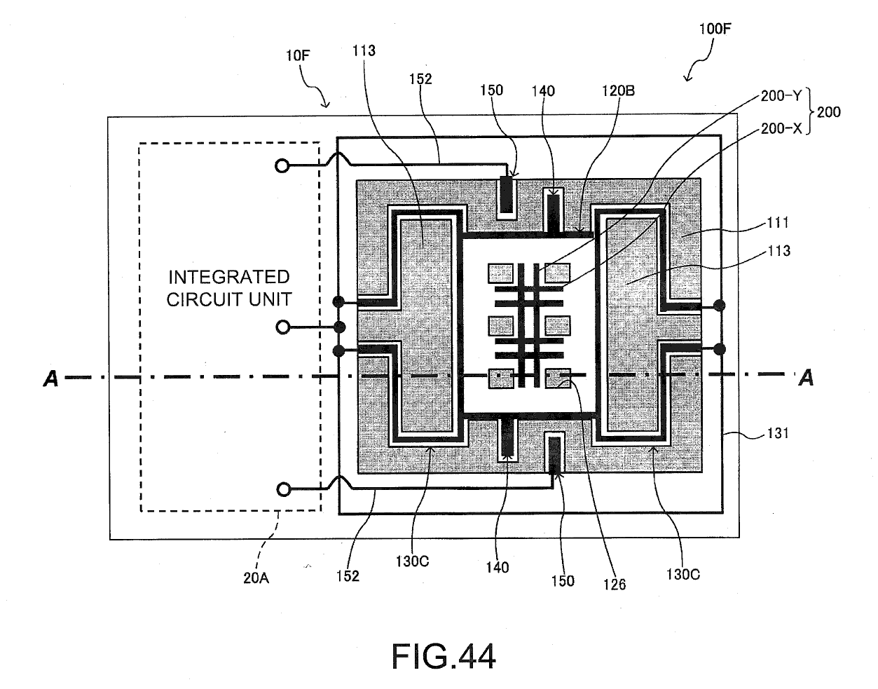

FIG. 44 illustrates a sixth embodiment according to the invention. The sixth embodiment applies the technique of the third embodiment (reduction of the wiring layers and the plugs in the elastic deformation portions) to the second embodiment (isolated pattern in the movable weight). In the following explanation, only the points of the sixth embodiment different from the second embodiment are touched upon.

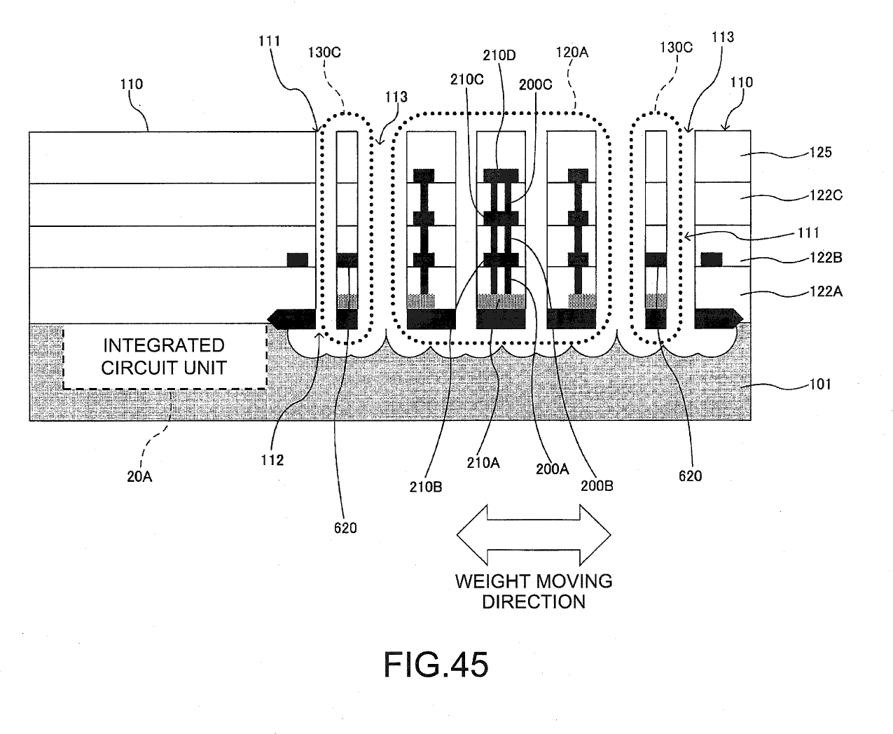

Though an acceleration sensor module 10F shown in FIG. 44 is different from the second embodiment in that an acceleration sensor 100F has the elastic deformation portions 130C, FIG. 44 is substantially identical to FIG. 16. However, FIG. 45 as a cross-sectional view taken along a line A-A in FIG. 44 is different from FIG. 17 as a cross-sectional view taken along a line A-A in FIG. 16. The elastic deformation portions 130A shown in FIG. 17 have a vertical cross section including the four conductive layers and the three plugs connecting these conductive layers. However, the elastic deformation portions 130C shown in FIG. 45 include a conductive layer 620 only on the same layer as the conductive layer 210B of the movable weight 120B, and do not have conductive layers nor plugs on the other layers.

Thus, even in the structure including the cavity portions 113 in the elastic deformation portions 130C in the sixth embodiment, the elastic deformation force of the elastic deformation portions 130C can be increased by providing the conductive layers on a smaller number of layers than the plural conductive layers 210A through 210D formed in the movable weight 120B similarly to the fifth embodiment.

### 7. Seventh Embodiment

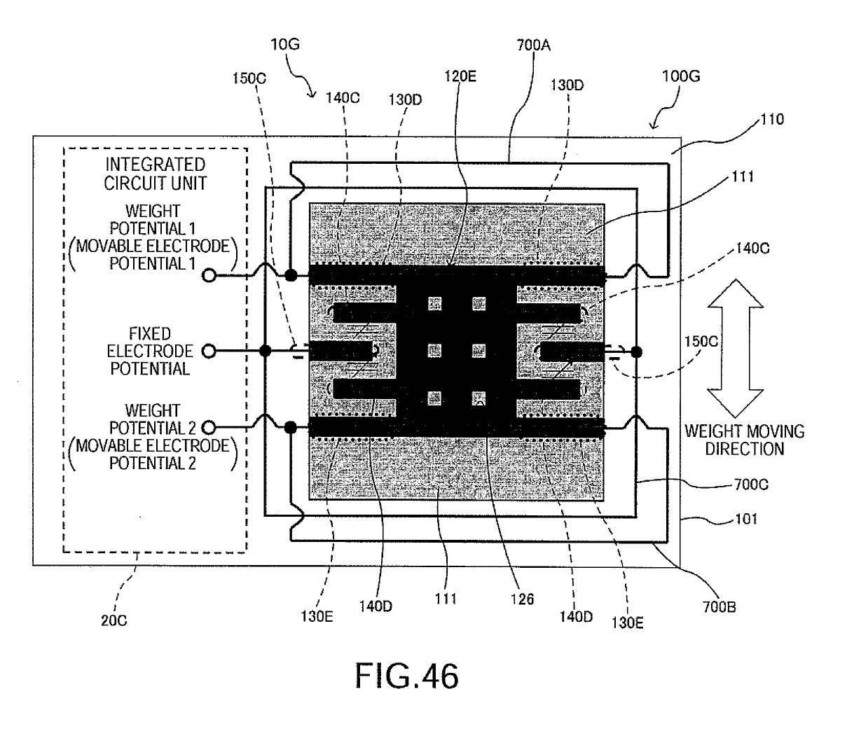

FIG. 46 illustrates a seventh embodiment of the invention. According to the seventh embodiment, the potentials of the plural fixed electrode units are set at equal potentials, and the potentials of the plural movable electrode units are set at different potentials unlike the first through sixth embodiments which set the potentials of the plural movable electrode units at equal potentials. Thus, plural potential wires are provided in the elastic deformation portions.

An acceleration sensor module 10G shown in FIG. 46 has an acceleration sensor 100G and an integrated circuit unit 20C connected with the acceleration sensor 100G. The integrated circuit unit 20C receives one fixed electrode potential and two movable electrode potentials.

The acceleration sensor 100G is connected with the fixed frame 110 via four elastic deformation portions 130D and 130E, for example, and has a movable weight 120E provided with the cavity portion 111 around the movable weight 120E. Two fixed electrode units 150C project from the fixed frame 110 toward the cavity portion 111. On the other hand, two movable electrode units 140C and two movable electrode units 140D project from the movable weight 120E toward the cavity portion 111 in such positions as to be opposed to both sides of the two fixed electrode units 150C. The one fixed electrode unit 150 and the two movable electrode units 140C constitute a comb-teeth-shaped electrode unit.

The potentials of the movable electrode units 140C disposed on the side of one of the fixed electrode units 150C in the weight moving direction are set at equal potentials by an annular wire 700A provided on the movable weight 120E, the two elastic deformation portions 130C and 130C, and the fixed frame 110, and inputted to the integrated circuit unit 20C. The potentials of the two movable electrode units 140D disposed on the side of the other fixed electrode unit 150C in the weight moving direction are set at equal potentials by an annular wire 700B provided on the movable weight 120E, the two elastic deformation portions 130D and 130D, and the fixed frame 110, and inputted to the integrated circuit unit 20C. The potentials of the two fixed electrode units 150C, 150C are set at equal potentials by an annular wire 700C provided on the fixed frame 110, and inputted to the integrated circuit unit 20C. The integrated circuit unit 20C has a structure similar to that of the circuit shown in FIG. 4.

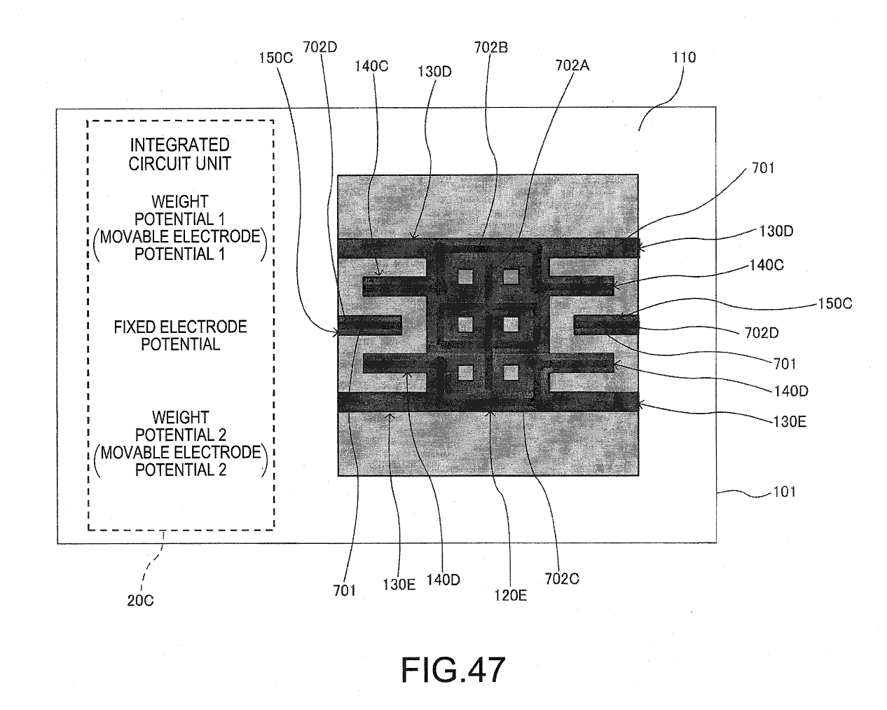

FIG. 47 illustrates a first conductive layer (polysilicon layer). The first conductive layer provided on the movable weight 120E includes an isolated conductive layer 702A formed only for increasing the mass of the movable weight 120E, a conductive layer 702B wiring between the two movable electrode units 140C, and a conductive layer 702C wiring between the two movable electrode units 140D, all of which layers 702A through 702C are disposed on abase oxide film 701. Each of the two fixed electrode units 150C, 150C also includes a conductive layer 702D on the base oxide film.

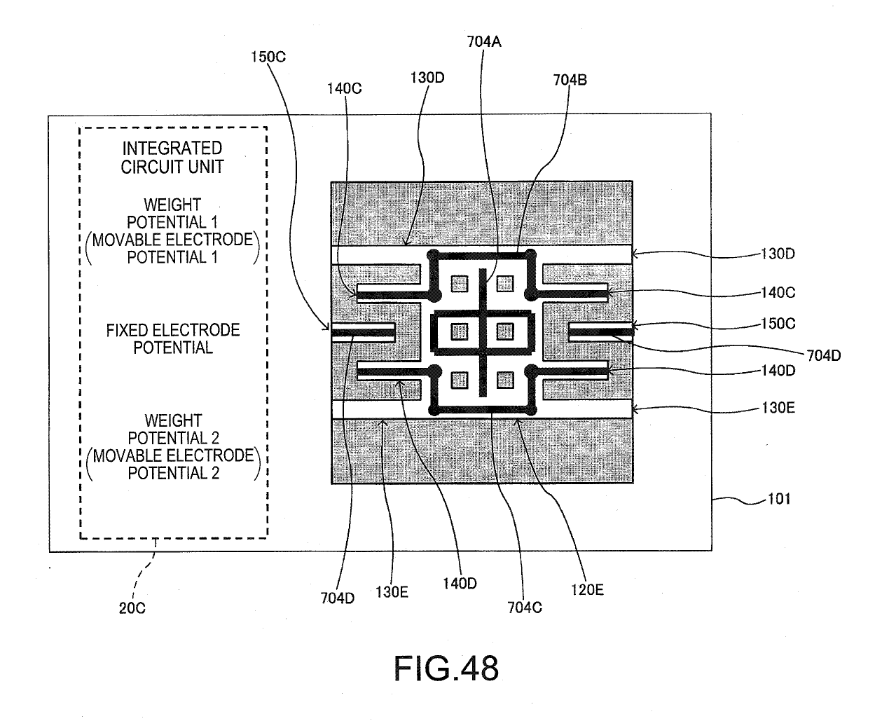

FIG. 48 illustrates a first plug layer to contact the first conductive layer. The first plug layer includes first plugs 704A, 704B, 704C, and 704D to contact the first conductive layers 702A, 702B, 702C, and 702D, respectively. The first plugs 704A, 704B, and 704C formed on the movable weight 120E and having wall portions in the wall shapes extending in the longitudinal directions of the orthogonal two axes on the two-dimensional plane contribute to increase in the mass of the movable weight 120E.

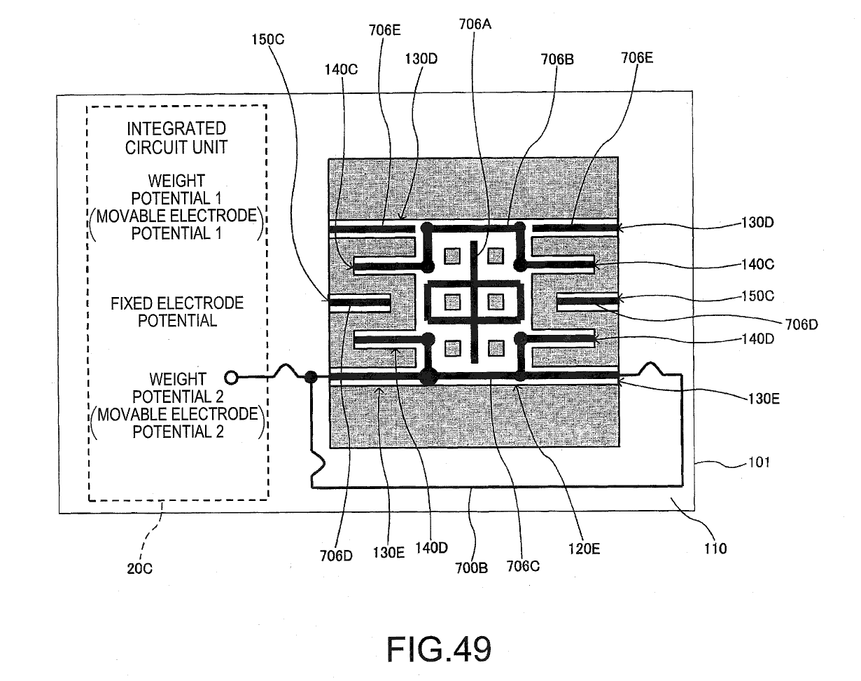

FIG. 49 illustrates a second conductive layer (first metal layer). The second conductive layer includes second conductive layers 706A, 706B, 706C, and 706D connected with the first plugs 704A, 704B, 704C, and 704D, respectively. The second conductive layer has a wiring layer 700B disposed in the area of the two elastic deformation portions 130E, 130E and the fixed frame 110 for inputting the same potentials of the two movable electrode units 140D, 140D to the integrated circuit unit 20C. For balancing the structure, second conductive layers 706E, 706E having isolated patterns are provided on the other two elastic deformation portions 130D, 130D.

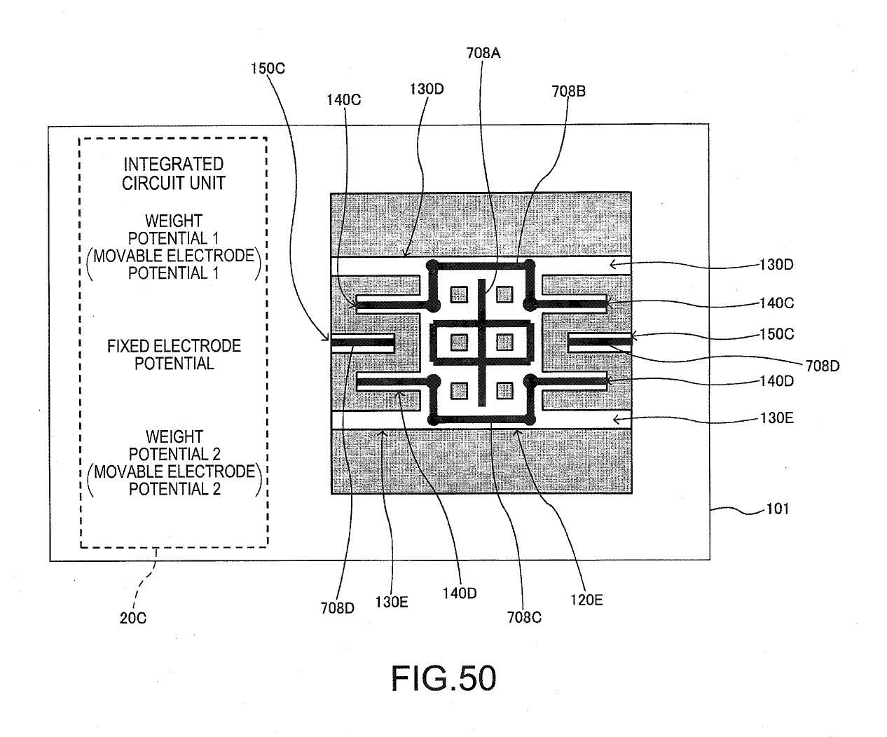

FIG. 50 illustrates a second plug layer to contact the second conductive layer. The second plug layer includes second plugs 708A, 708B, 708C, and 708D to contact the second conductive layers 706A, 706B, 706C, and 706D, respectively. The second plugs 708A, 708B, and 708C formed on the movable weight 120E and having wall portions in the wall shapes extending in the longitudinal directions of the orthogonal two axes on the two-dimensional plane contribute to increase in the mass of the movable weight 120E.

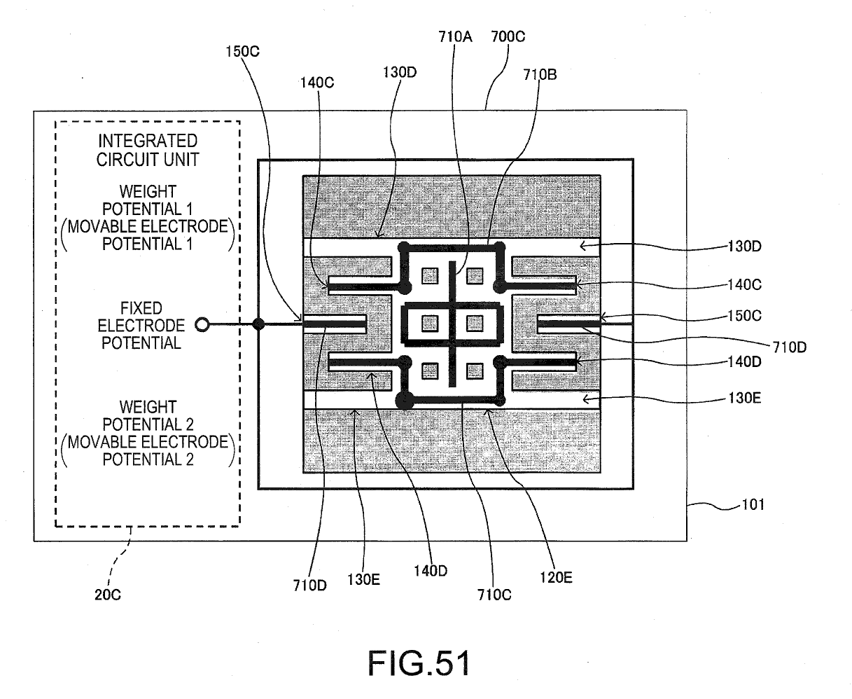

FIG. 51 illustrates a third conductive layer (second metal layer). The third conductive layer includes third conductive layers 710A, 710B, 710C, and 710D connected with the second plugs 708A, 708B, 708C, and 708D, respectively. The third conductive layer has a wiring layer 700C disposed in the area of the fixed frame 110 for inputting the same potentials of the two fixed electrode units 150C to the integrated circuit unit 20C.

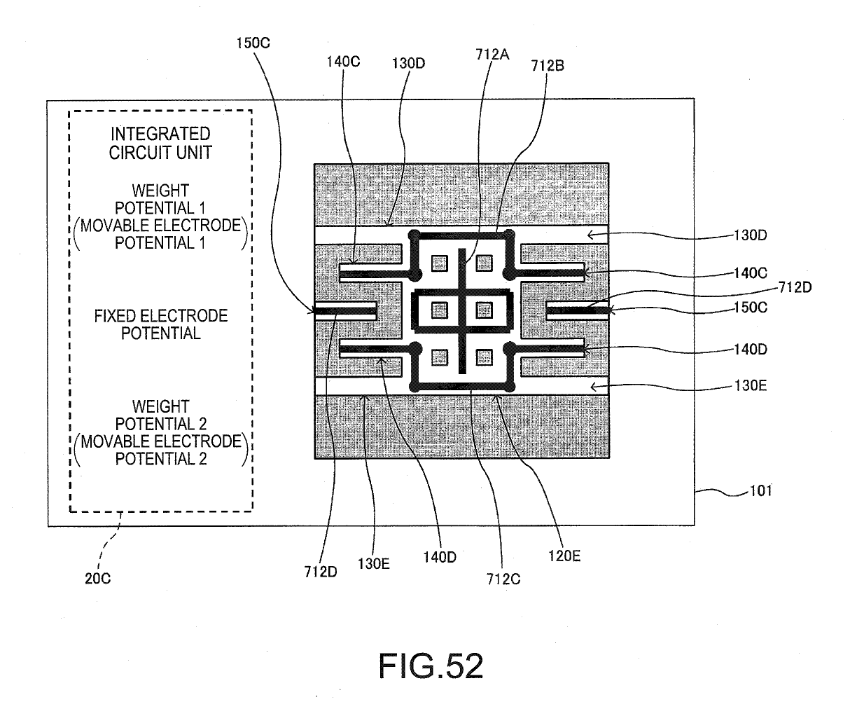

FIG. 52 illustrates a third plug layer to contact the third conductive layer. The third plug layer includes third plugs 712A, 712B, 712C, and 712D to contact the third conductive layers 710A, 710B, 710C, and 710D, respectively. The third plugs 712A, 712B, and 712C formed on the movable weight 120E and having wall portions in the wall shapes extending in the longitudinal directions of the orthogonal two axes on the two-dimensional plane contribute to increase in the mass of the movable weight 120E.

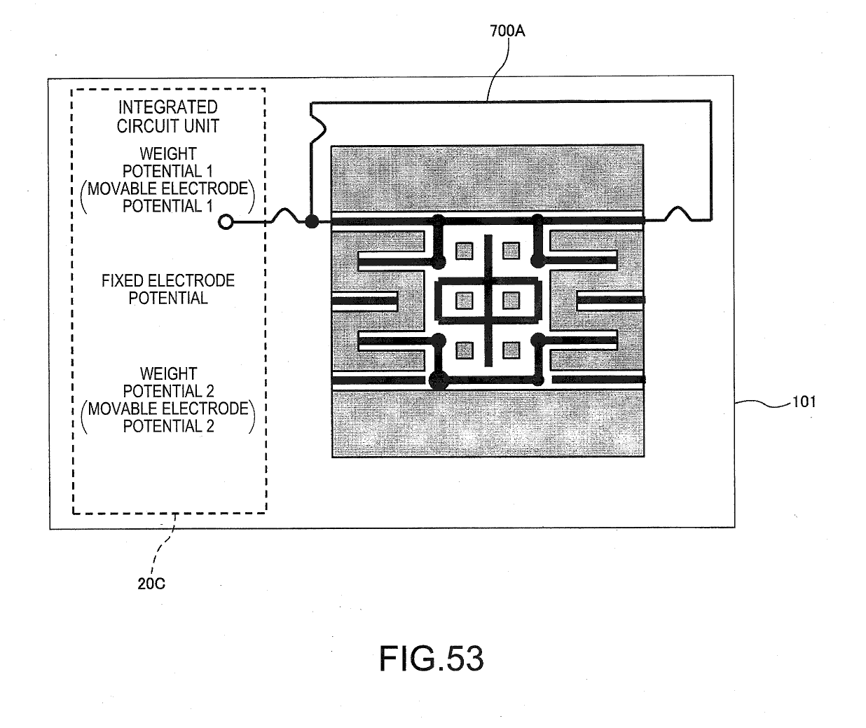

FIG. 53 illustrates a fourth conductive layer (third metal layer). The fourth conductive layer includes fourth conductive layers 714A, 714B, 714C, and 714D connected with the third plugs 712A, 712B, 712C, and 712D, respectively. The fourth conductive layer has the wiring layer 700A disposed in the area of the two elastic deformation portions 130D, 130D and the fixed frame 110 for inputting the same potentials of the two movable electrode units 140C, 140C to the integrated circuit unit 20C. For balancing the structure, fourth conductive layers 714E, 714E having isolated patterns are provided on the other two elastic deformation portions 130E, 130E.

The acceleration sensor module 10G shown in FIG. 46 as an example has a substrate size of 3 mm×3 mm, a contour of 1 mm×1 mm for the cavity portion 111, and a length of 0.2 mm for the elastic deformation portions 130D and 130E. The comb-teeth electrode having distance of 0.002 mm between the electrodes has a total number of about 100 electrode pairs and a total capacity of about 1 to 2 pF. The mass of the movable weight 120E is several micrograms such as 3×10⁻⁶ to 4×10⁻⁶ g.

### 8. Modified Example

While the preferred embodiments have been described in detail, it is easily understood by those skilled in the art that many modifications and changes can be made without substantially departing from the scope of the invention in providing novel matters and advantages. As such, it is intended that all of these modified examples are included in the scope of the invention. For example, any terms used in association with different terms having wider or identical definitions at least once can be replaced with the different terms at any points of the specification or the drawings.

For example, the MEMS sensor according to the invention is not limited to the electrostatic capacity type acceleration sensor but may be applied to a piezo-resistance type acceleration sensor. Moreover, the invention is applicable to any physical sensors as long as they can detect changes of electrostatic capacity produced by movement of a movable weight. For example, the invention is applicable to a gyro-sensor, a pressure sensor and others.

As apparent from comparison between FIG. 1 and FIG. 46, the MEMS sensor according to an aspect of the invention can at least detect the level of physical quantity by using the opposed electrodes having variable distances but cannot detect the direction in which the physical quantity acts. For overcoming this drawback, the MEMS sensor according to another aspect of the invention includes at least one fixed electrode unit and a plurality of movable electrode units which are formed integrally with the movable weight and increase and decrease the distances from the at least one fixed electrode unit by moving at least in one axial direction (for example, the comb-teeth electrode shown in FIG. 46).

The physical quantity detection principle is based on the fact that the level and direction of the physical quantity can be detected from increase in one of the two between-electrodes distances and decrease in the other between-electrodes distance produced when the plural movable electrode units move along with the movable weight with respect to the at least one fixed electrode unit according to the relationship between the level of the electrostatic capacity and the increase and decrease dependent on the between-electrodes distances. The detection axis of the physical quantity is not limited to one axis or two axes but may be three or more axes.

The present invention is not limited to this; the MEMS sensor also can be used for electronic device such as a digital camera, a car navigation system, a mobile phone, a mobile personal computer, a game controller. According to this structure, it is able to improve detection sensitivity by the MEMS sensor.

The entire disclosure of Japanese Patent Application No. 2009-059048, filed Mar. 12, 2009 and No. 2010-043844, filed Mar. 1, 2010 are expressly incorporated by reference herein.

What is claimed is:

1. An MEMS sensor comprising:
a movable weight which is connected with a fixed frame via an elastic deformation portion,
wherein
the movable weight has a laminated layer structure including a conductive layer and an insulation layer,
the insulation layer is embedded a plug, and the plug has specific gravity larger than that of the insulation layer.

2. The MEMS sensor according to claim 1, further comprising:
a fixed electrode unit extending from the fixed frame in the form of a arm; and
a movable electrode unit extending from the movable weight and disposed opposed to the fixed electrode unit through a gap in the form of a arm,
wherein the fixed electrode unit and the movable electrode unit are arranged a first direction.

3. The MEMS sensor according to claim 2,
wherein the movable weight has a plane including the first direction and a second direction perpendicular to the first direction in planar view, and the movable weight has a center line bisected with a width of the second direction, and the plug is formed line symmetry for the center line in the movable weight.

4. The MEMS sensor according to claim 1, wherein the conductive layer is formed the plural; the insulation layer is formed between a plurality of the conductive layer.

5. The MEMS sensor according to claim 4, wherein: the plug is a electrical conducting material, and the plug is formed passing through the insulation layer, and each of the conductive layer is connected by the plug.

6. The MEMS sensor according to claim 1, wherein the movable weight has a through hole penetrated from a top layer to a bottom layer, the plug is formed in proximity to the through hole.

7. The MEMS sensor according to claim 2, wherein the plug has a first plug connected electrically the movable electrode unit and a second plug isolated electrically the movable electrode unit.

8. The MEMS sensor according to claim 1, wherein an integrated circuit unit is formed in proximity to the fixed frame, the integrated circuit unit is formed by the use of the laminated layer structure.

9. An electronic device comprising the MEMS sensor according to claim 1.

10. An MEMS sensor manufacturing method for an MEMS sensor having a movable weight which is connected with a fixed frame via an elastic deformation portion, comprising:
forming a laminated layer structure which laminates a conductive layer and a insulation layer on a substrate;
forming a groove on the insulation layer, and inserting a plug in the groove, the plug has specific gravity larger than that of the insulation layer;
patterning the laminated layer structure by anisotropic etching to form a first cavity portion as an opening through which the surface of the substrate is exposed; and
isotropically etching the substrate via the first cavity portion to form a second cavity portion between the substrate and the laminated layer structure.
